(19) United States
(12) Patent Application Publication
(10) Pub. No.: US 2026/0219020 A1
(43) Pub. Date: Jul. 30, 2026

(54) POSITION SENSING

(71) Applicant: CAMBRIDGE INTEGRATED CIRCUITS LIMITED, Cambridge Cambridgeshire (GB)

(72) Inventor: David ELY, Cambridge Cambridgeshire (GB)

(73) Assignee: CAMBRIDGE INTEGRATED CIRCUITS LIMITED, Cambridge Cambridgeshire (GB)

(21) Appl. No.: 19/145,181

(22) PCT Filed: Dec. 18, 2023
(86) PCT No.: PCT/GB2023/053291

§ 371 Date: Jul. 1, 2025

(30) Foreign Application Priority Data
Jan. 9, 2023 (GB) 2300293.4

(51) Int. Cl. G01B 7/00; G01D 5/20; H05K 1/02

(52) U.S. Cl. CPC G01B 7/003; G01D 5/2086; H05K 1/0216

(57) ABSTRACT

Position sensors are arranged to inductively sense the position of a target relative to a number of sensor coils. Excitation circuitry reduces power lost in the circuit. Sensor coil and resonator coil designs optimize the magnetic coupling between the resonator coil and the sensor coils. Resonator coil designs reduce coupling between the resonator coil and a metal shaft to which the resonator coil is mounted during use. Sensor coil designs improve the accuracy of one or more coarse sensing coils in the presence of misalignment between the sensor coils and a resonator coil. Control circuitry is for controlling the energizing of the resonator coil.

The present invention relates to position sensors, to parts thereof and to position sensing methods. The invention has particular, although not exclusive, relevance to inductive position sensors that can measure the position of a target, and is applicable to machines, robotics, vehicle traction motors, and instrumentation, and other applications where such a measurement is required.

Inductive position sensors for sensing the position of a target are well known. U.S. Pat. Nos. 5,815,091, 7,019,672, 6,304,014, 6,534,970, GB2461448, GB2488389 and GB2500522 describe examples of such inductive position sensors that sense the position of a resonant circuit. Typically, the resonant circuit is mounted on the moveable part whose position is to be sensed by sensor circuitry mounted on a sensor board. The sensor circuitry includes an excitation coil for energising the resonant circuit and plural sensor coils for sensing the signal generated by the resonator when energised. The resonant circuit and the sensor coils are arranged so that the signals generated in the sensor coils vary with the position to be measured (which may be a rotation angle of a rotating part or the position of a moveable part along a given path). Processing electronics then process the signals from the sensor coils to work out the position of the resonant circuit. Typically, fine sensor coils (coils having high position sensing accuracy) are used, but whilst these can provide accurate position sensing across a measuring range, their output repeats along the measuring range so there is an ambiguity in their position reading. To address this problem coarse sensor coils (coils that have less accuracy) are provided which, although they have less accuracy, are able to resolve the ambiguity in the fine sensor measurements.

There is a need to make various improvements to this kind of inductive position sensor and to parts thereof. Specifically, there is a need to provide more energy efficient excitation circuitry that is used to energise the resonant circuitry; there is a need to design more efficient sensor coils to enable improved sensing of the signals generated by the resonant circuit; there is a need for improved designs of resonant circuits to provide resonant circuits having higher Q-factor—which improves the coupling of energy between the excitation coil and the resonant circuit and between the resonant circuit and the sensor coils; there is a need for improved resonant circuit layout that minimises coupling between the resonant circuit and metal located in a through hole around which the resonant circuit is arranged; and there is a need for improved sensor coil layouts that allow for improved accuracy particularly in the presence of misalignment between the sensor coils and the resonant target. Embodiments of the present invention seek to at least alleviate one or more of the problems discussed above or elsewhere in this patent application.

### SUMMARY OF INVENTION

The present invention provides a transducer for an inductive position sensor comprising: first and second members mounted for relative movement along a measurement path; wherein the first member comprises: at least one coarse sensor coil having sensor coil portions that are spatially arranged over a measurement path to provide coarse position sensing information; and at least one fine sensor coil having sensor coil portions that are spatially arranged over the measurement path to provide fine position sensing information; wherein the second member comprises a magnetic field generator having first and second magnetic field generating portions, wherein the first magnetic field generating portion comprises plural sets of coil loops that are spatially arranged over the measurement path to correspond to the sensor coil portions of the at least one fine sensor coil and wherein the second magnetic field generating portion comprises at least first and second sets of coil loops that are spatially arranged over the measurement path in an anti-symmetric manner; wherein the first set of coil loops of the second magnetic field generating portion overlaps with a third set of coil loops which is one of said plural sets of coil loops of the first magnetic field generating portion; wherein the sets of coil loops of the first and second magnetic field generating portions are connected together so that when a current is flowing in the sets of coil loops of the magnetic field generator: i) a current flow direction of the current in the first set of coil loops is opposite to a current flow direction of the current in the second set of coil loops; and ii) a current flow direction of the current in the third set of coil loops is the same as the current flow direction of the current in the first set of coil loops.

The at least one coarse sensor coil may comprise first and second sets of coil loops spaced apart over the measurement path and connected in series so that an Electro Motive Force, EMF, generated in the first set of coil loops by a common magnetic field opposes the EMF generated in the second set of coil loops by the common magnetic field.

In some embodiments, the magnetic field generator comprises a resonator.

The measurement path may be circular and the first and second sets of coil loops may be arranged on either side of a diameter of the circular measurement path.

The at least one fine sensor coil typically has a repeating pattern of sensor coil portions arranged over the measurement path and the plural sets of coil loops of the first magnetic field generating portion will typically have a set of coil loops corresponding to each repetition of the repeating pattern of the sensor coil portions.

The present invention also provides a transducer for an inductive position sensor comprising a printed circuit board carrying a plurality of sensor coils including first and second coarse sensor coils for providing coarse position information, first and second fine sensor coils for providing fine position information and an excitation coil for energising a target; wherein the plurality of sensor coils are formed by conductor tracks on different layers of the printed circuit board that are connected together to define the plurality of sensor coils at a plurality of vias that connect together conductors on the different layers of the printed circuit board; wherein the printed circuit board comprises a through hole, a first plurality of vias arranged in first and second rings around the through hole and a second plurality of vias arranged in a third ring in proximity to an outer edge of the printed circuit board; wherein the fine sensor coils include radial conductor portions on a first layer of the printed circuit board that extend from vias in the first or second rings to vias in the third ring, wherein radial conductor portions of a fine sensor coil are connected to other radial conductor portions of the same fine sensor coil on a second layer and wherein conductor coil portions of at least one coarse sensor coil or conductor coil portions of the excitation coil run in a space between the first and second rings of vias.

In some embodiments, conductor coil portions of at least one coarse sensor coil run in a space between the first and second rings of vias. In addition or alternatively, conductor coil portions of the excitation coil run in a space between the first and second rings of vias.

The present invention also provides a transducer comprising a multi-layer printed circuit board, each layer comprising conductor portions that connect together through the layers at a plurality of vias to define a plurality of coil loop portions; wherein the printed circuit board includes a through hole and the plurality of coil loop portions include a first subset of coil loop portions, a second subset of coil loop portions and a third subset of coil loop portions; wherein loops defined by the first subset of coil loop portions and the second subset of coil loop portions do not enclose the through hole and are arranged peripherally around the through hole; wherein loops defined by the third subset of coil loop portions enclose the through hole; wherein the plurality of coil loop portions are connected together so that a current flow direction in the first subset of coil loop portions is opposite to a current flow direction in the second subset of coil loop portions and is the same as a current flow direction in the third subset of coil loop portions, whereby when current flows through the first, second and third subsets of coil loop portions, magnetic fields generated by the plurality of coil loop portions combine to reduce a net magnetic flux through said through hole.

The plurality of coil loop portions may be arranged so that when current flows through the first, second and third subsets of coil loop portions, magnetic fields generated by the plurality of coil loop portions combine to minimise the net magnetic flux through said through hole.

In a preferred embodiment, the plurality of coil loop portions are arranged so that when current flows through the first, second and third subsets of coil loop portions, magnetic fields generated by the plurality of coil loop portions combine so that there is no (or substantially no) net magnetic flux through said through hole. Whilst it is preferred that there is exactly no net magnetic flux through the through hole, it is difficult to ensure that there is exactly no net magnetic flux through the through hole and so reference to no net magnetic flux used in this specification is intended to cover there being exactly no net magnetic field as well as there being some negligible amount of net magnetic flux passing through the through hole.

The first subset of coil loop portions may comprise more coil loop portions than the second subset of coil loop portions. In some embodiments, each coil loop portion defines a plurality of coil loops.

Typically, the plurality of coil loop portions are connected to one or more capacitors to form a resonant circuit.

In some embodiments, in the through hole, the magnetic fields generated by the second and third subsets of coil loop portions balance with the magnetic fields generated by the first subset of coil loop portions, thereby minimising magnetic coupling between any metal in the through hole and the plurality of coil loop portions.

The present invention also provides excitation circuitry for energising an excitation coil to excite a resonant target of an inductive position sensor, the excitation circuitry comprising: an impedance network that is coupled, in use, to the excitation coil and having a first state that presents a first impedance that is primarily capacitive to the excitation coil and a second state that presents a second impedance to the excitation coil, wherein the magnitude of the second impedance is at least twice that of the first impedance when measured at the target's resonant frequency; drive circuitry for driving the excitation coil via the impedance network with an excitation current to cause the excitation coil to generate an excitation magnetic field for energising the resonant target; and a controller for controlling the drive circuitry and the impedance network so that in a first time period, the impedance network is configured in said first state and the drive circuitry is configured to drive the excitation coil with said excitation current and so that in a second time period, the impedance network is configured in said second state and the drive circuitry is configured not to drive the excitation coil with said excitation current.

The second impedance may be primarily resistive, such that the resistive part of the second impedance is greater than the magnitude of the reactive part of the second impedance when measured at the target's resonant frequency. In other embodiments, the second impedance may be an open circuit.

In some embodiments, the impedance network comprises at least one a capacitor that is coupled, in use, to the excitation coil and at least one resistive impedance that is couplable to and decouplable from the capacitor. The control circuitry may be arranged to decouple the at least one resistive impedance from the at least one capacitor during said first period and to couple the at least one resistive impedance to the at least one capacitor during said second period. In some embodiments, the control circuitry is configured to couple the at least one resistive impedance in series with the at least one capacitor for reducing current flow in the excitation coil during the second period.

Typically, during the first time period, a resonant frequency of the excitation coil and the impedance network is between 1.5 and 6 times a resonant frequency of the resonant target.

The present invention also provides a digital waveform generator for controlling the driving of an excitation coil of a position sensor via a bridge drive circuit having first and second switches that are connected in series with each other and to a terminal of the excitation coil (the connection to the terminal of the excitation coil may be a direct connection or an indirect connection through some intermediate component, such as a resistor or a capacitor), each switch having a first terminal and a second terminal that are open circuit when the switch is open and that are short circuited when the switch is closed, the digital waveform generator comprising means for generating a first control signal that opens and closes the first switch and means for generating a second control signal that opens and closes the second switch; wherein the digital waveform generator is configured: i) to generate said first control signal and said second control signal to cause first and second reference voltages to be applied in an alternating manner to the terminal of the excitation coil via the bridge circuit, ii) to generate said first control signal and said second control signal so that the first and second switches do not close at the same time, and iii) to control the timing of the closing of the first switch or the second switch, during the alternating application of said first and second reference voltages to the terminal of the excitation coil, to be at points in time when a voltage at the first terminal of the switch is within a given tolerance of a voltage at the second terminal of the switch.

The means for generating the first control signal may be configured to generate a first train of pulses, adjacent pulses of which being arranged to open and close the first switch, wherein the means for generating the second control signal may be configured to generate a second train of pulses, adjacent pulses of which being arranged to open and close the second switch and wherein the first and second trains of pulses are interleaved in time to cause said first and second reference voltages to be applied in an alternating manner to the terminal of the excitation coil via the bridge circuit.

Typically, during an excitation period, a first and/or a last pulse in the first train of pulses is shorter in duration than the other pulses in the first train of pulses and a first and/or a last pulse in the second train of pulses is shorter in duration than the other pulses in the second train of pulses.

In some embodiment, the given tolerance is within twenty percent of a difference in voltage between the first and second reference voltages, and preferably within ten percent of a difference in voltage between the first and second reference voltages.

Preferably, the digital waveform generator is configured to control the timing of the switching on of the first switch or the second switch, during the alternating application of said first and second reference voltages to the terminal of the excitation coil, to be at points in time when the voltage at the first terminal of the switch is expected to be the same as the voltage at the second terminal of the switch.

The digital waveform generator may also comprise an input for receiving an input signal indicating the voltage on the first terminal of the first switch and may determine a timing for said first control signal to close said first switch in dependence upon the received input signal. The digital waveform generator may output the first control signal to close the first switch when the input signal indicates that the voltage of the first terminal of the first switch is greater than a first threshold. The first threshold typically depends on the larger of the first and second reference voltages.

The digital waveform generator may comprise an input for receiving an input signal indicating the voltage on the second terminal of the second switch and wherein the digital waveform generator is configured to determine a timing for said second control signal to close said second switch in dependence upon the received input signal.

The digital waveform generator may output the second control signal to close the second switch when the input signal indicates that the voltage of the second terminal of the second switch is less than a second threshold. Typically, the second threshold depends upon the lower of the first and second reference voltages.

In some embodiments, the digital waveform generator comprises inputs for receiving signals indicating the first and second reference voltages (alternatively, these may be values stored in memory) and wherein the digital waveform generator is configured to determine the timing of the first and second control signals depending on the signals indicating the first and second reference signals.

The digital waveform generator may monitor (track) the voltage difference between the first and second terminals of the first switch when the first switch is open and may control the timing of the closing of the first switch in dependence upon the monitored voltage difference. Similarly, the digital waveform generator may monitor the voltage difference between the first and second terminals of the second switch when the second switch is open and may control the timing of the closing of the second switch in dependence upon the monitored voltage difference.

The digital waveform generator may generate the first control signal and the second control signal to cause the first and second reference voltages to be applied in an alternating and periodic manner to the terminal of the excitation coil via the bridge circuit.

The digital waveform generator may generate the first and second control signals so that a period of time between when the first switch opens and the second switch closes is between 0.5% and 8% of a period of said periodic alternating application of said first and second reference voltages to the terminal of the excitation coil. Similarly, a period of time between when the second switch opens and the first switch closes is between 0.5% and 8% of the period of said periodic alternating application of said first and second reference voltages to the terminal of the excitation coil.

The invention also provides an integrated circuit for a position sensor, the integrated circuit comprising the above described digital waveform generator and processing circuitry for processing signals received in sensor coils to determine position information of a resonant target relative to the sensor coils.

These and other aspects of the invention will become apparent from the following detailed description of embodiments described with reference to the accompanying drawings in which:

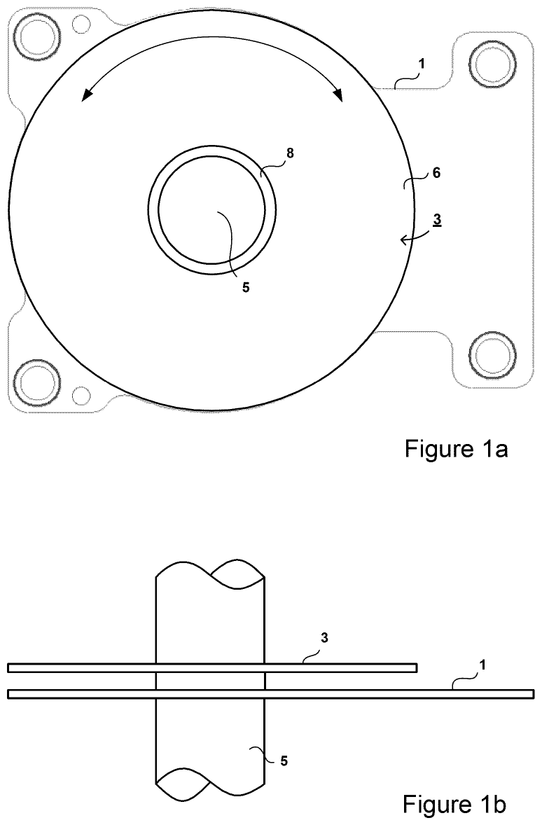

FIG. 1a is a plan view and FIG. 1b is a side view of a sensor board and a resonator circuit board that is mounted for rotation with a rotatable shaft that passes through a central hole of the sensor board, the sensor circuit board carrying an excitation coil and sensor coils and the resonator circuit board carrying a resonant circuit;

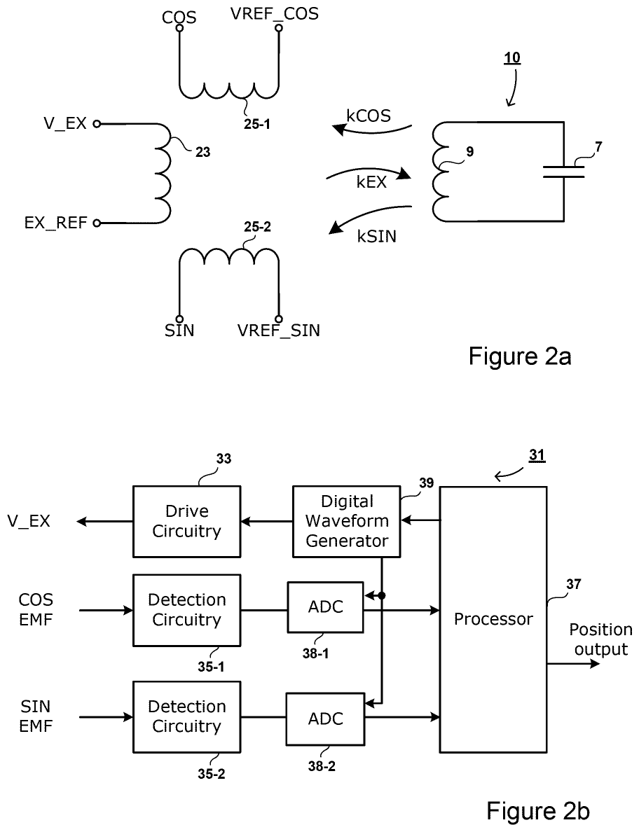

FIG. 2a is an electric equivalent circuit illustrating the sensor coils and the excitation coil carried on the sensor circuit board that inductively couple with a resonant circuit carried on the resonator circuit board shown in FIG. 1;

FIG. 2b is a block diagram illustrating the main components of excitation and processing circuitry used to energise the resonant circuit illustrated in FIG. 2a and used to detect the position of the target from signals induced in the sensor coils;

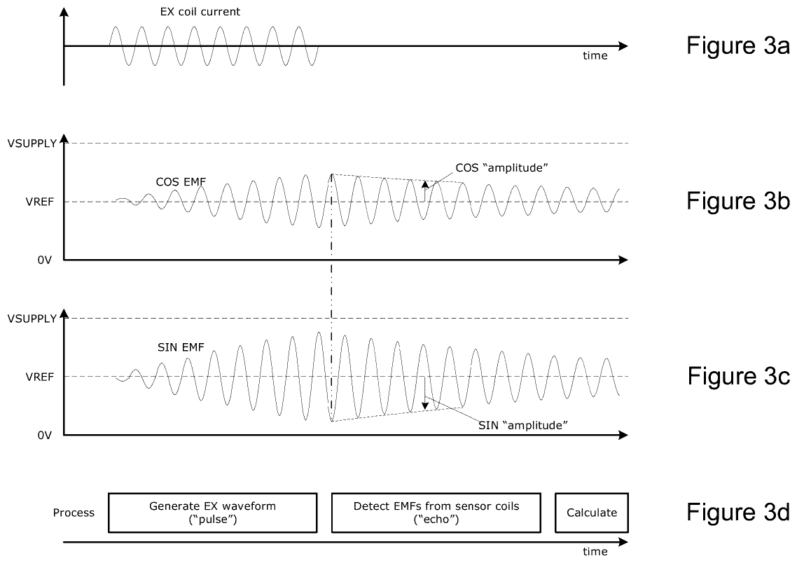

FIG. 3a illustrates a burst of excitation signal that is applied to the excitation coil;

FIG. 3b illustrates a signal generated in the COS sensor coil by the resonant circuit;

FIG. 3c illustrates a signal generated in the SIN sensor coil by the resonant circuit;

FIG. 3d illustrates the overall “pulse-echo” timing and the timing of the position calculation using the signals generated in the sensor coils;

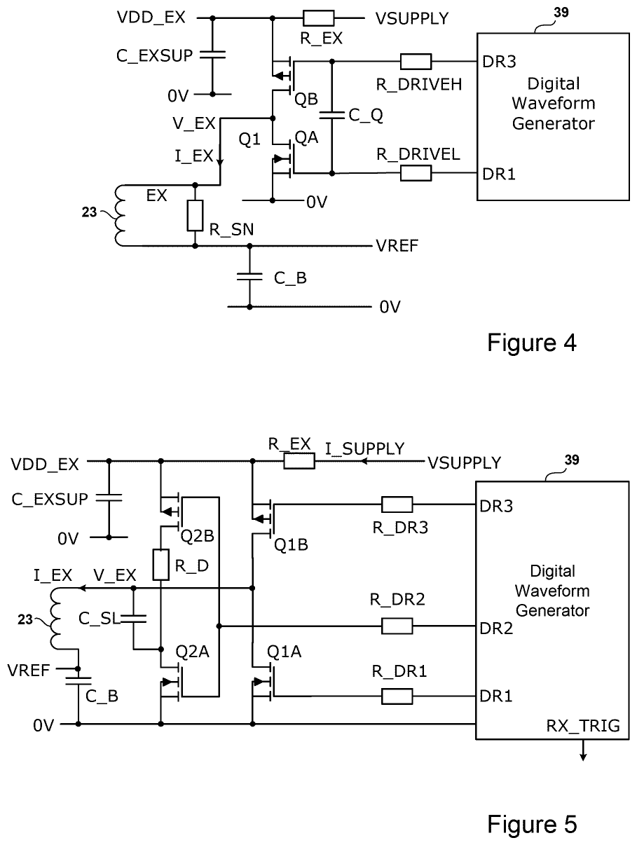

FIG. 4 is a prior art circuit diagram illustrating the way in which the excitation circuitry controls the driving of the excitation coil that is used to energise the resonant circuit;

FIG. 5 is a circuit diagram illustrating an improved way in which the excitation circuitry controls the driving of the excitation coil that is used to energise the resonant circuit;

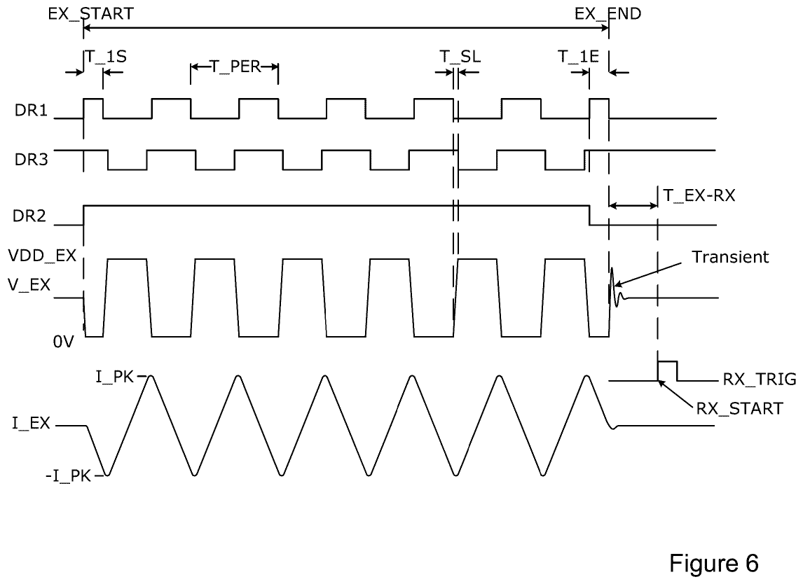

FIG. 6 is a timing diagram illustrating the timing of various signals generated in the circuit shown in FIG. 5;

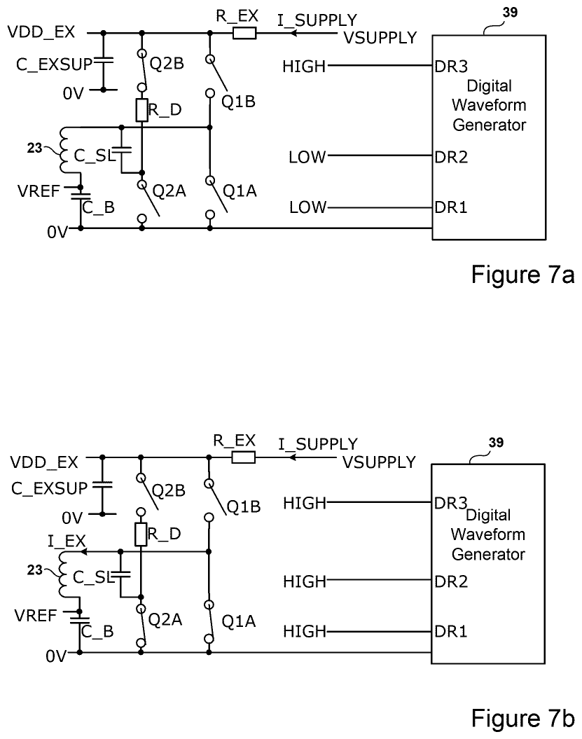

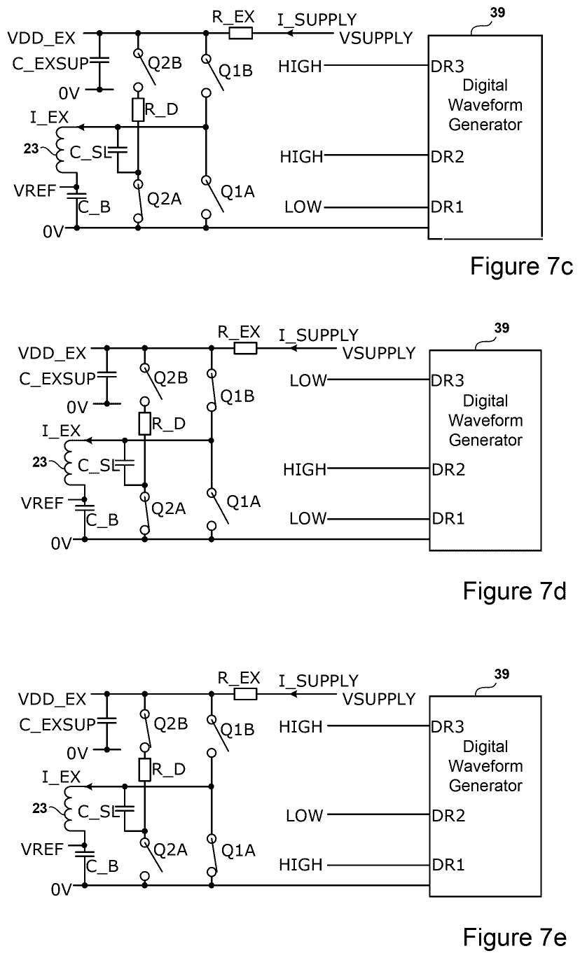

FIG. 7a schematically illustrates the circuitry shown in FIG. 5 when the switches shown in FIG. 5 are in a first combination of states;

FIG. 7b schematically illustrates the circuitry shown in FIG. 5 when the switches shown in FIG. 5 are in a second combination of states;

FIG. 7c schematically illustrates the circuitry shown in FIG. 5 when the switches shown in FIG. 5 are in a third combination of states;

FIG. 7d schematically illustrates the circuitry shown in FIG. 5 when the switches shown in FIG. 5 are in a fourth combination of states;

FIG. 7e schematically illustrates the circuitry shown in FIG. 5 when the switches shown in FIG. 5 are in a fifth combination of states;

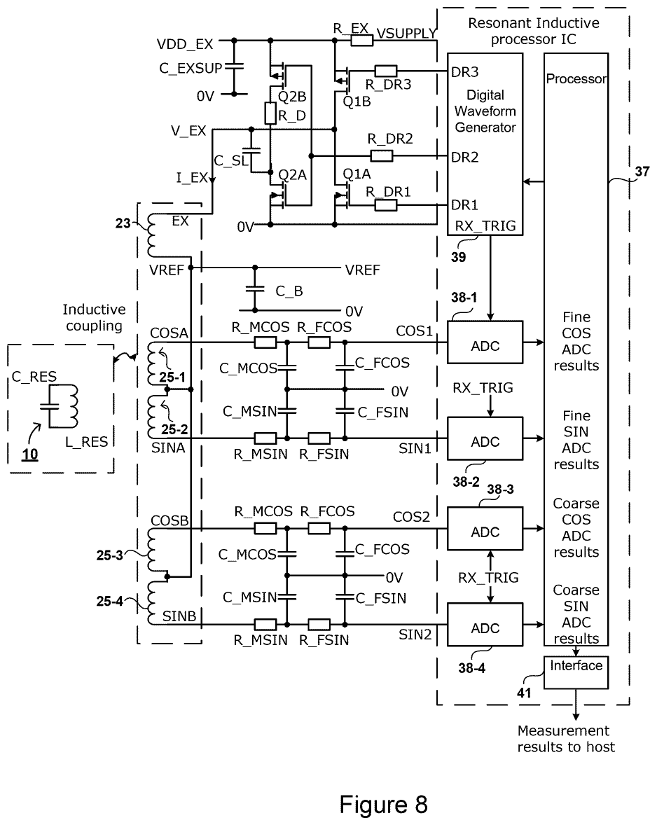

FIG. 8 schematically illustrates the position sensor circuitry including the excitation circuitry, the sensor circuitry, the resonant circuit, a digital waveform generator and a processor for determining the position of the resonant circuit;

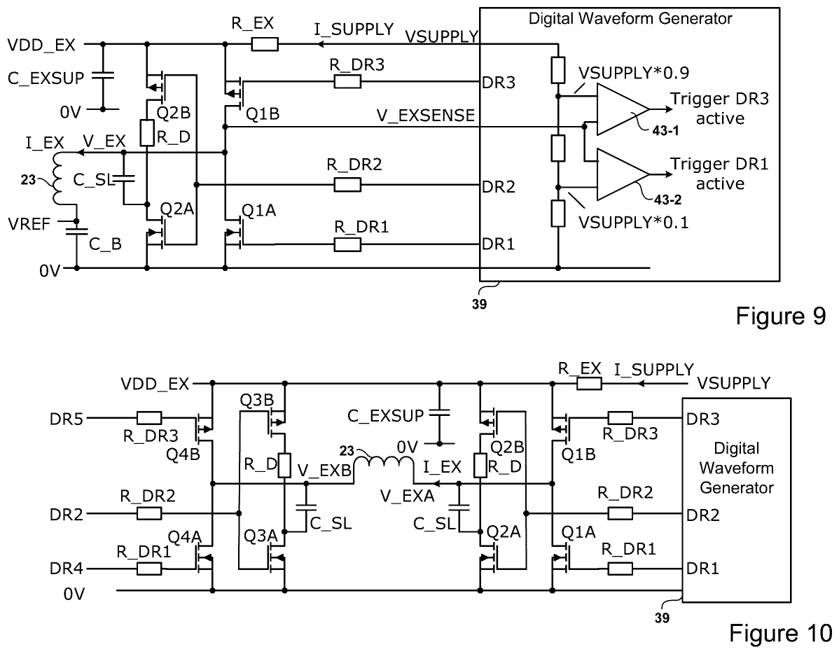

FIG. 9 illustrates first alternative excitation circuitry that can be used instead of the excitation circuitry shown in FIG. 5;

FIG. 10 illustrates second alternative excitation circuitry that can be used instead of the excitation circuitry shown in FIG. 5;

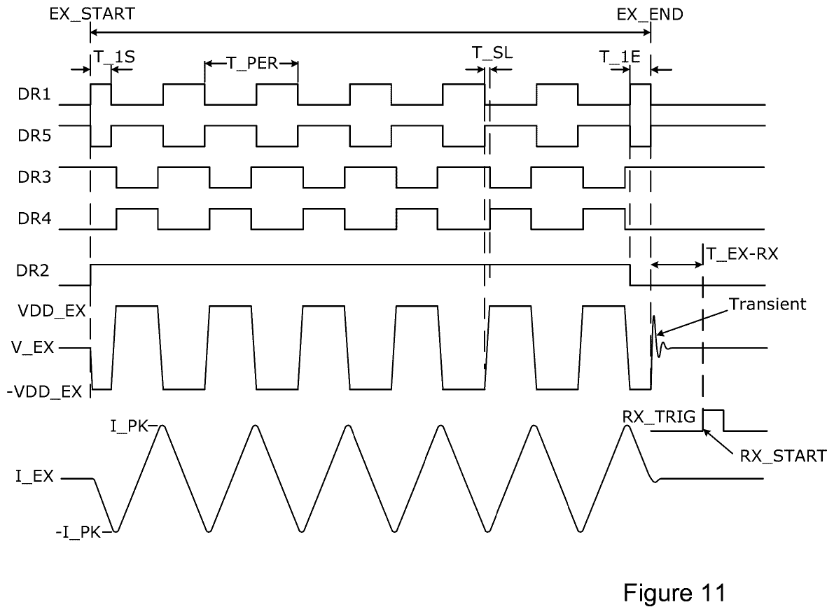

FIG. 11 is a timing diagram illustrating the timing of various signals generated in the circuit shown in FIG. 10;

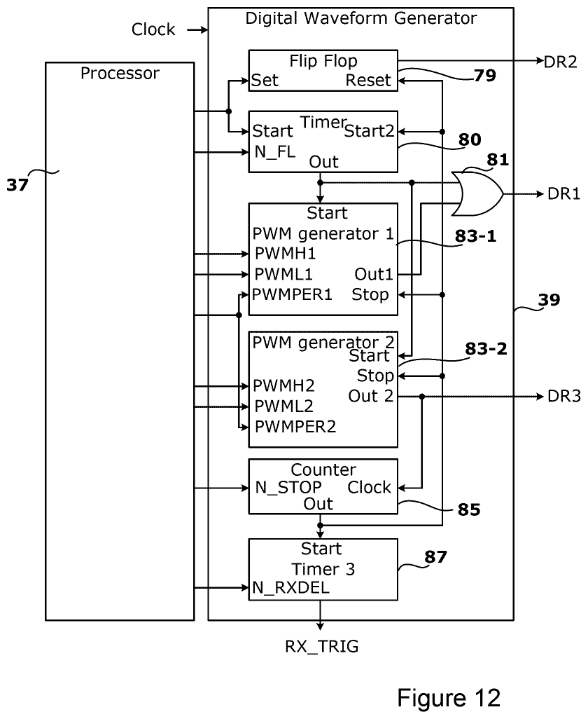

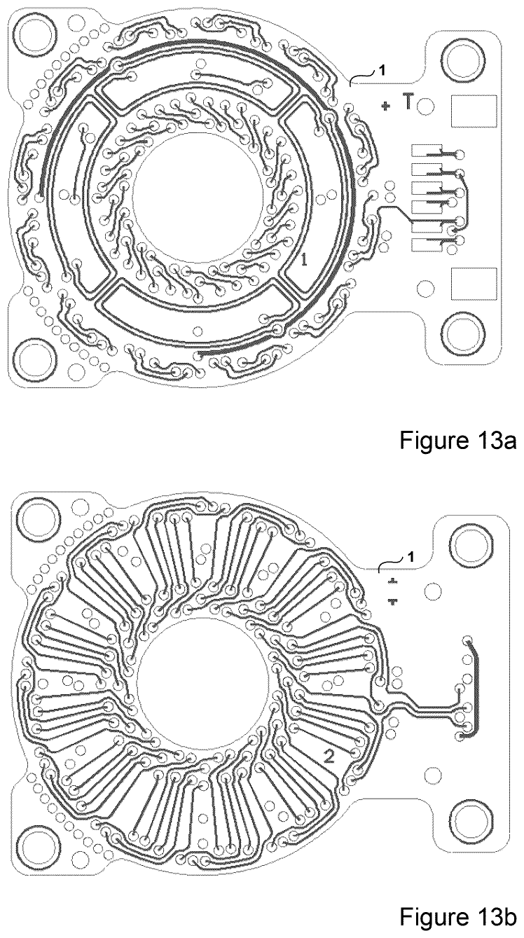

FIG. 12 is a block diagram of an exemplary digital waveform generator circuit;

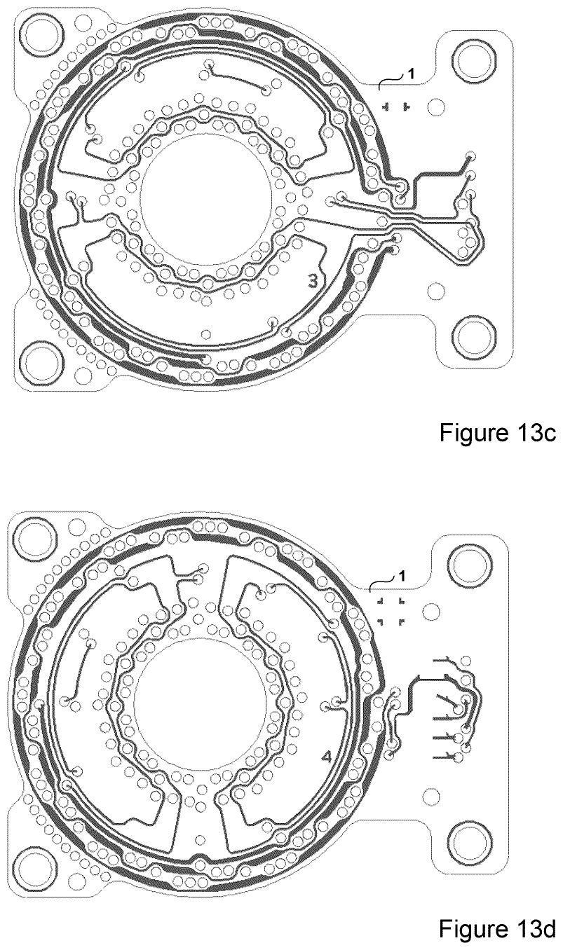

FIG. 13a illustrates a first layer of conductor tracks of the sensor board (PCB) shown in FIG. 1;

FIG. 13b illustrates a second layer of conductor tracks of the sensor board (PCB) shown in FIG. 1;

FIG. 13c illustrates a third layer of conductor tracks of the sensor board (PCB) shown in FIG. 1;

FIG. 13d illustrates a fourth layer of conductor tracks of the sensor board (PCB) shown in FIG. 1;

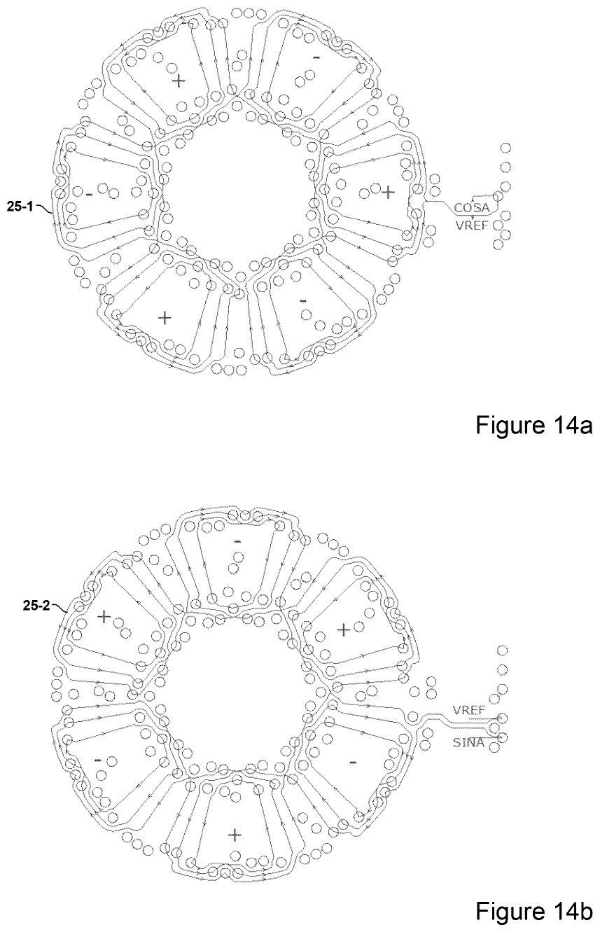

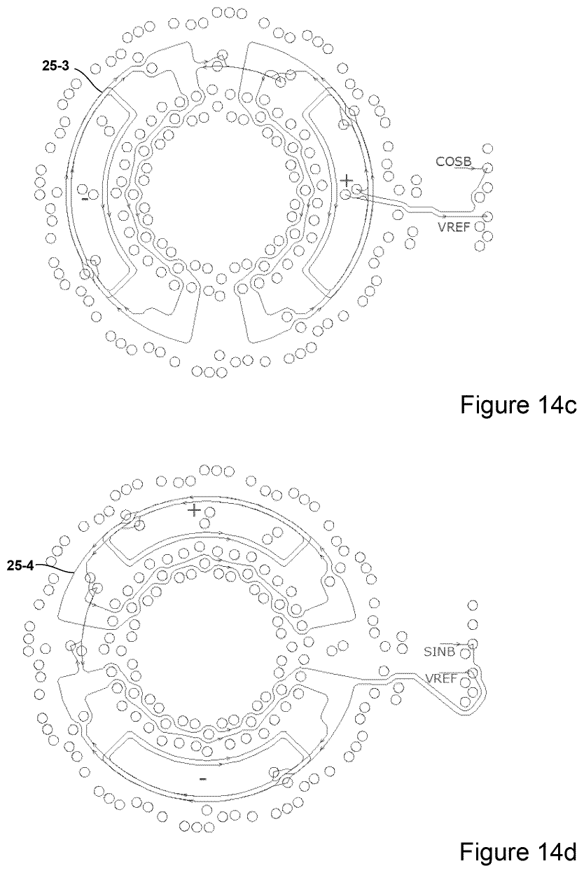

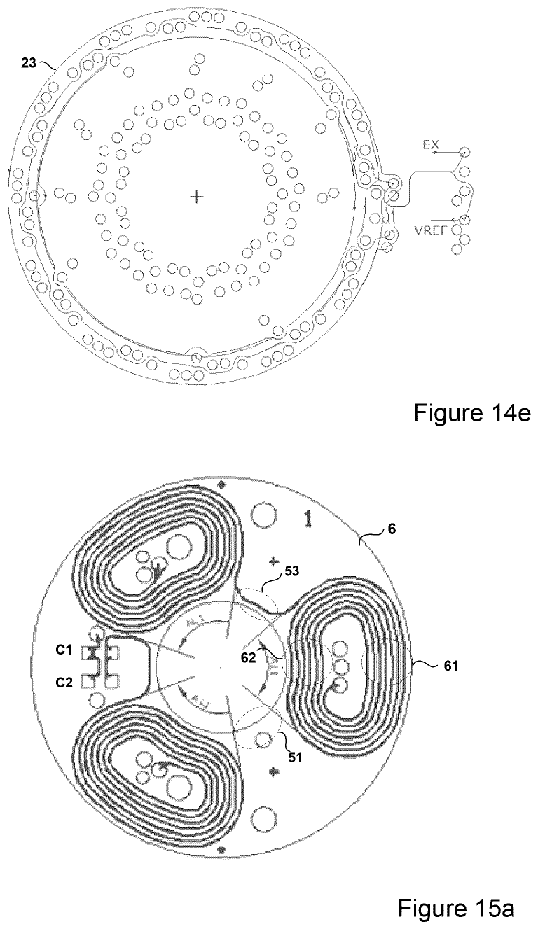

FIG. 14a illustrates the conductors of the sensor circuit board that form a fine COS sensor coil;

FIG. 14b illustrates the conductors of the sensor circuit board that form a fine SIN sensor coil;

FIG. 14c illustrates the conductors of the sensor circuit board that form a coarse COS sensor coil;

FIG. 14d illustrates the conductors of the sensor circuit board that form a coarse SIN sensor coil;

FIG. 14e illustrates the conductors of the sensor circuit board that form the excitation coil;

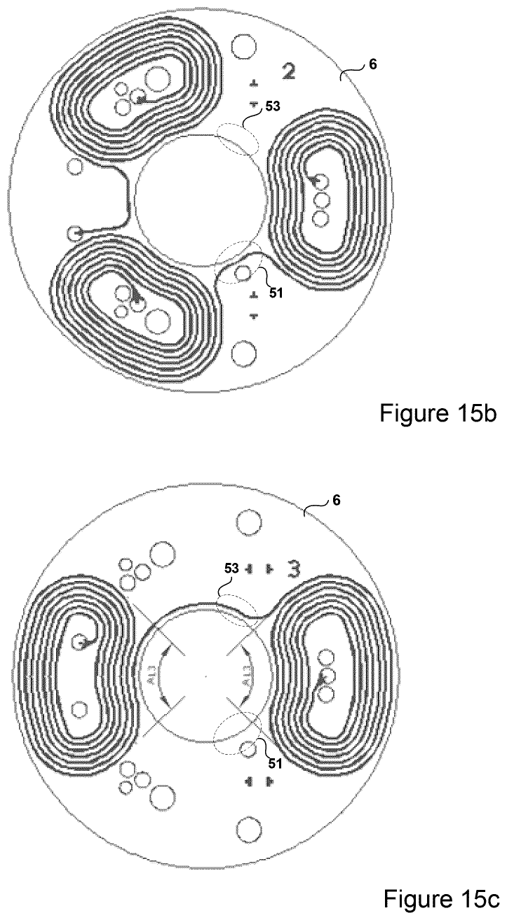

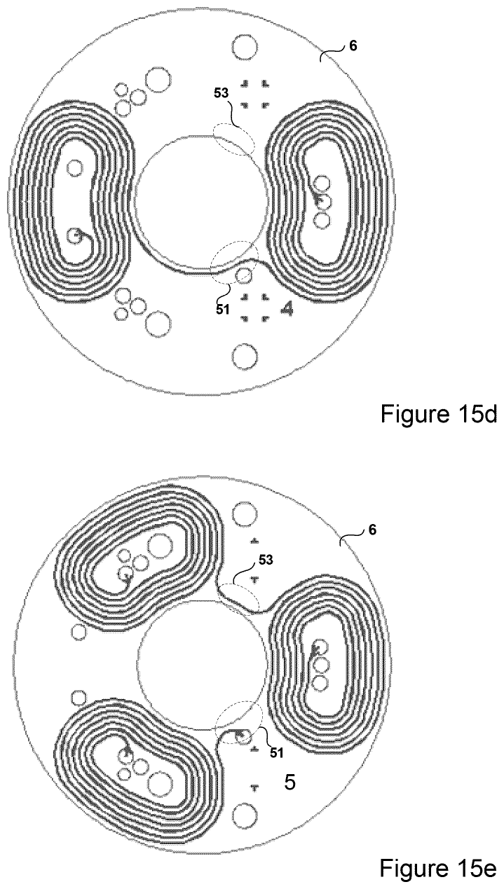

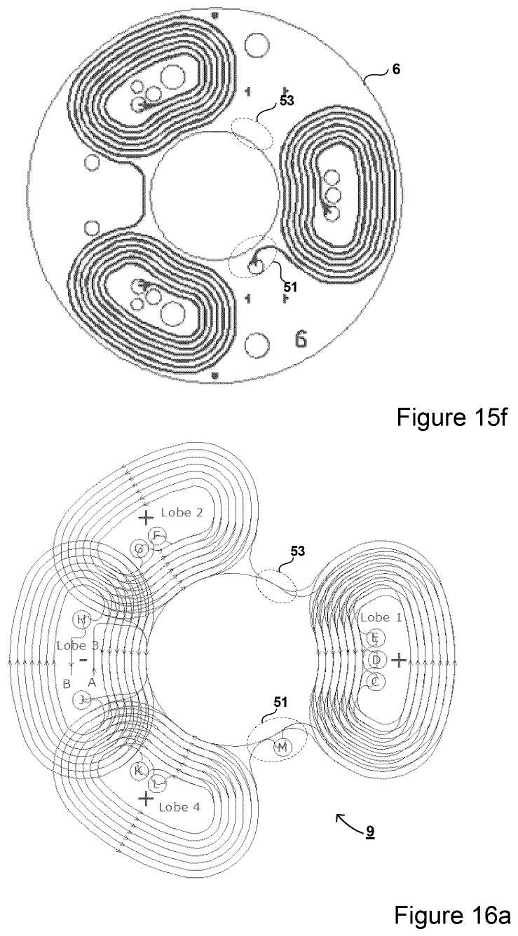

FIG. 15a illustrates a first layer of conductor tracks of the resonator circuit board (PCB) shown in FIG. 1;

FIG. 15b illustrates a second layer of conductor tracks of the resonator circuit board (PCB) shown in FIG. 1;

FIG. 15c illustrates a third layer of conductor tracks of the resonator circuit board (PCB) shown in FIG. 1;

FIG. 15d illustrates a fourth layer of conductor tracks of the resonator circuit board (PCB) shown in FIG. 1;

FIG. 15e illustrates a fifth layer of conductor tracks of the resonator circuit board (PCB) shown in FIG. 1;

FIG. 15f illustrates a sixth layer of conductor tracks of the resonator circuit board (PCB) shown in FIG. 1;

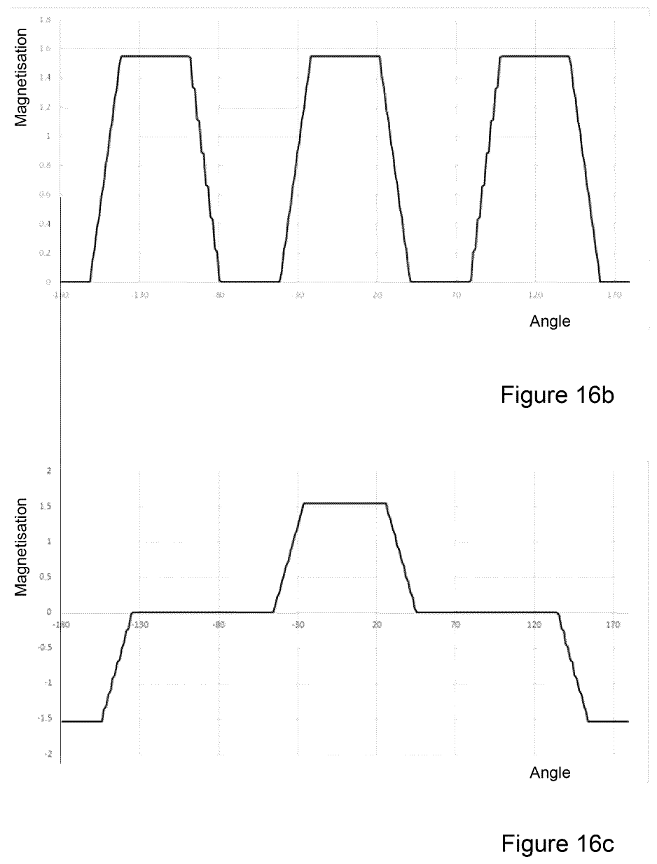

FIG. 16a illustrates the overlapping nature of the loop portions formed on the different layers of the resonator circuit board;

FIG. 16b illustrates a magnetisation pattern formed from a first subset of the loops forming part of the resonant circuit;

FIG. 16c illustrates a magnetisation pattern formed from a second subset of the loops forming part of the resonant circuit;

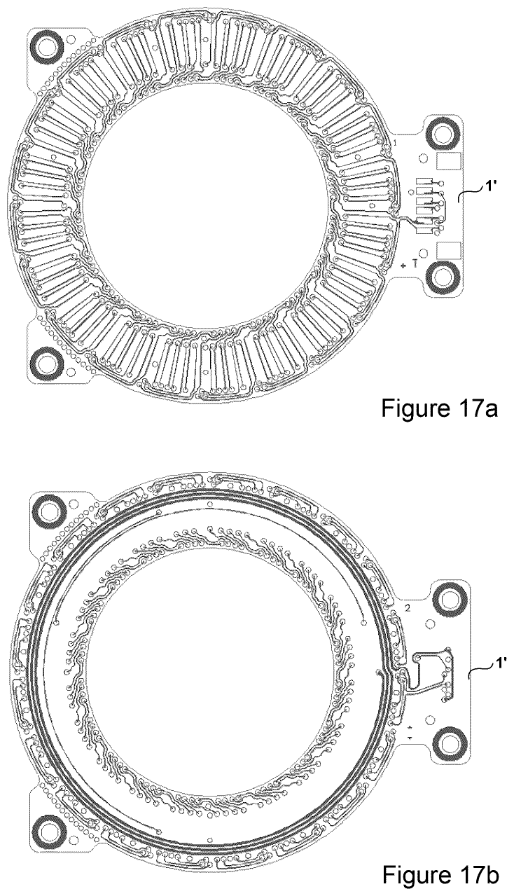

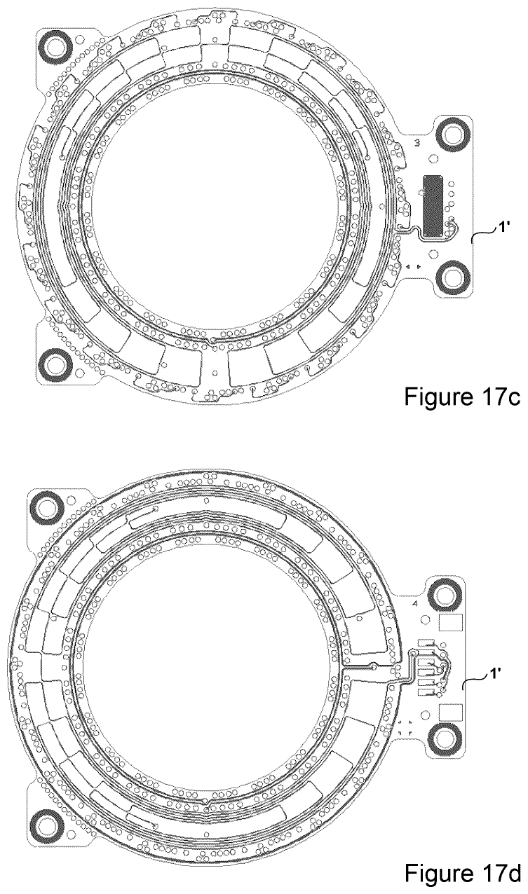

FIG. 17a illustrates a first layer of conductor tracks of an alternative sensor board (PCB) that can be used;

FIG. 17b illustrates a second layer of conductor tracks of the alternative sensor board (PCB);

FIG. 17c illustrates a third layer of conductor tracks of the alternative sensor board (PCB);

FIG. 17d illustrates a fourth layer of conductor tracks of the alternative sensor board (PCB);

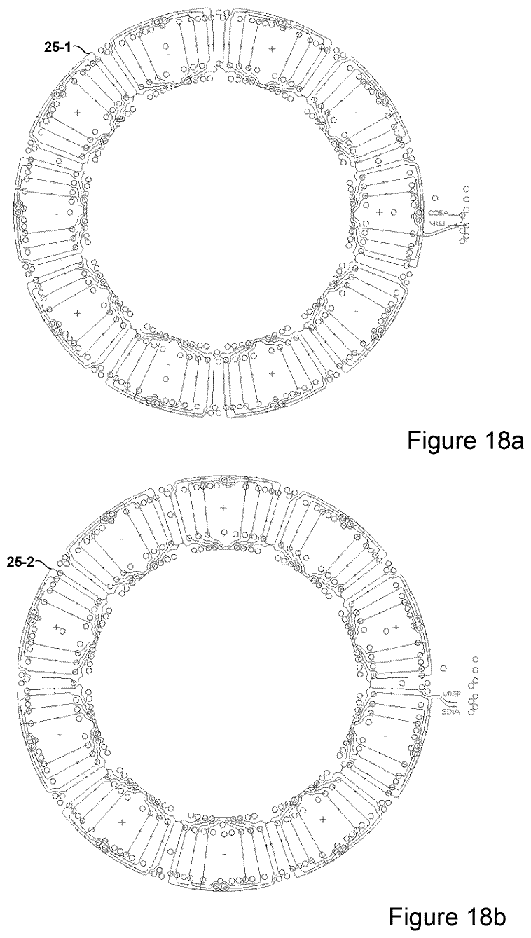

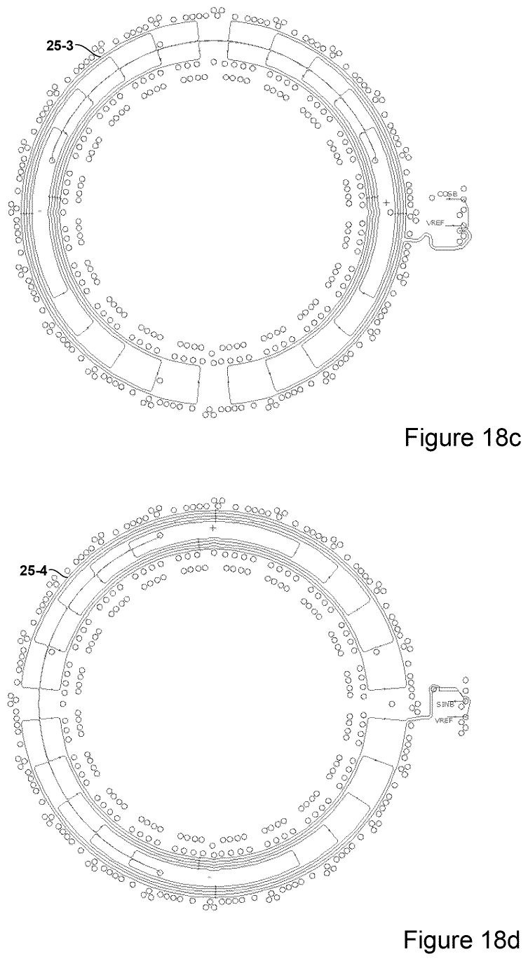

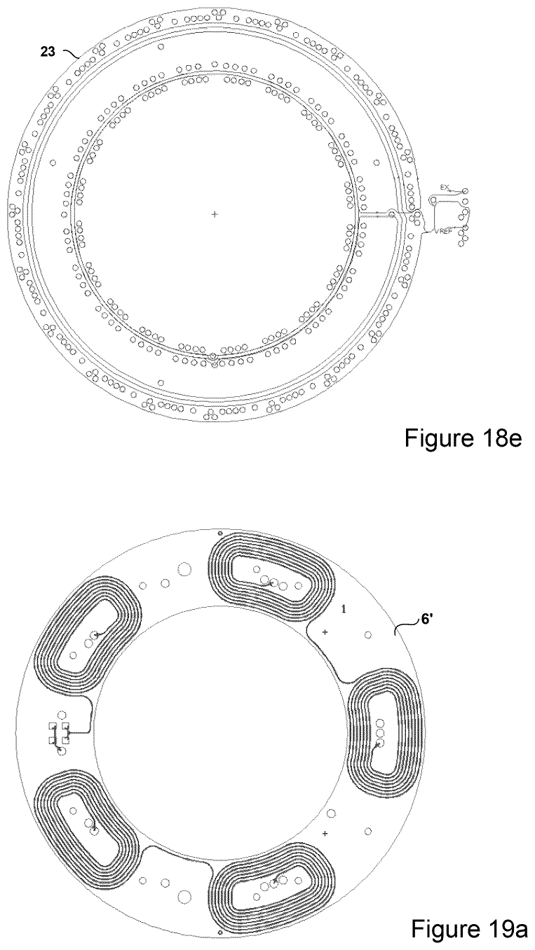

FIG. 18a illustrates the conductors of the alternative sensor circuit board shown in FIG. 17 that form a fine COS sensor coil;

FIG. 18b illustrates the conductors of the alternative sensor circuit board shown in FIG. 17 that form a fine SIN sensor coil;

FIG. 18c illustrates the conductors of the alternative sensor circuit board shown in FIG. 17 that form a coarse COS sensor coil;

FIG. 18d illustrates the conductors of the alternative sensor circuit board shown in FIG. 17 that form a coarse SIN sensor coil;

FIG. 18e illustrates the conductors of the alternative sensor circuit board shown in FIG. 17 that form the excitation coil;

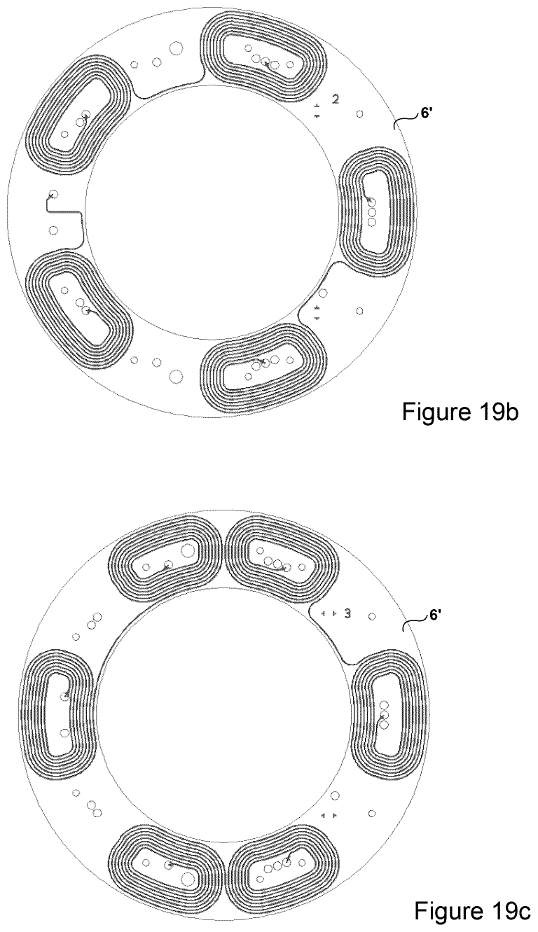

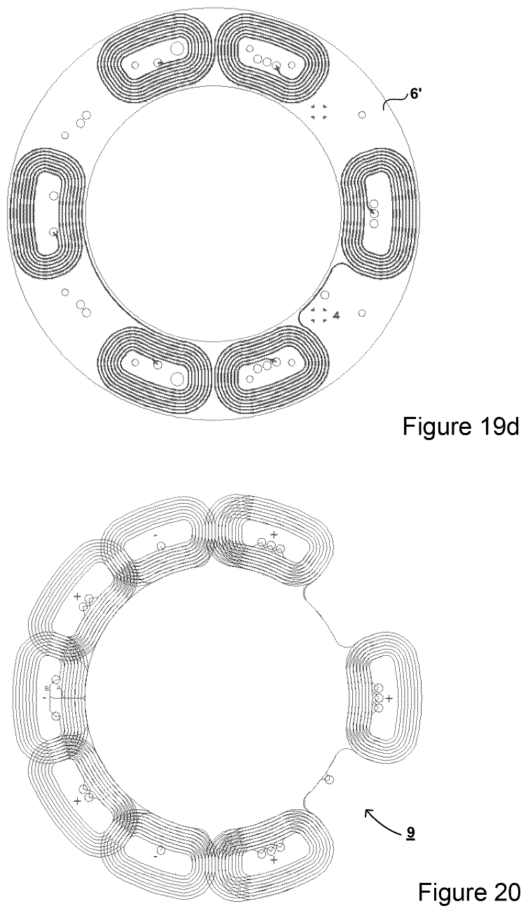

FIG. 19a illustrates a first layer of conductor tracks of a resonator circuit board (PCB) that can be used with the sensor board shown in FIG. 17;

FIG. 19b illustrates a second layer of conductor tracks of the resonator circuit board (PCB) that can be used with the sensor board shown in FIG. 17;

FIG. 19c illustrates a third layer of conductor tracks of the resonator circuit board (PCB) that can be used with the sensor board shown in FIG. 17;

FIG. 19d illustrates a fourth layer of conductor tracks of the resonator circuit board (PCB) that can be used with the sensor board shown in FIG. 17;

FIG. 20 illustrates the overlapping nature of the loop portions formed on the different layers of the resonator circuit board shown in FIG. 19; and

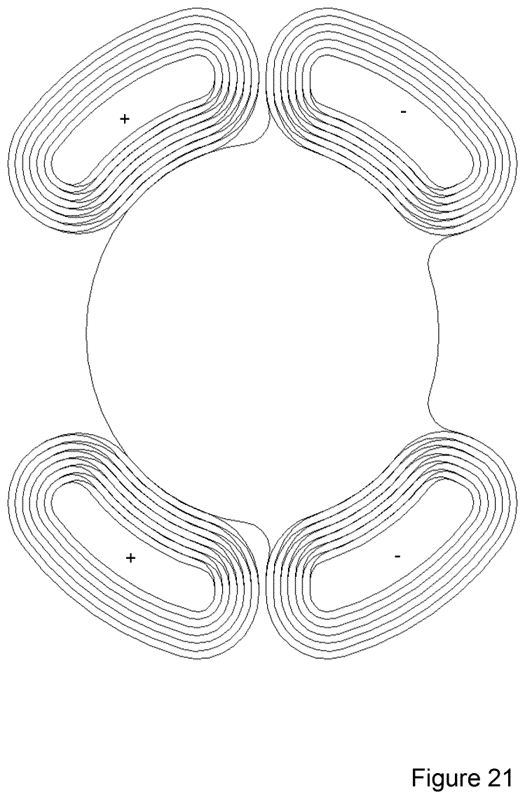

FIG. 21 illustrates an alternative arrangement of sets of loops that may form part of a resonator design of an alternative embodiment.

### BACKGROUND

FIG. 1a is a plan view and FIG. 1b is a side view of an inductive position sensor that is used to sense the angular position of a rotatable shaft 5. The sensor includes a sensor printed circuit board (PCB) 1 and a target 3 in the form of a resonator PCB 6. The sensor PCB 1 carries an excitation coil and a plurality of sensor coils and the resonator PCB 6 carries a resonant circuit 10. The sensor PCB 1 includes a through hole 8 at its centre large enough to accommodate the rotatable shaft 5 through the centre, as illustrated in FIG. 1a. The target 3 is mounted for rotation with the rotatable shaft 5.

Referring now to FIGS. 2a and 2b, the resonant circuit 10 carried by the resonator PCB 6 includes a resonator coil 9 that is defined by conductor tracks of the resonator PCB 6, and a capacitor 7 which is connected to the resonator coil 9. FIG. 2 also shows the excitation coil 23 and two sensor coils 25-1 and 25-2 that are formed by conductor tracks on the sensor PCB 1. The excitation coil 23 and the resonator coil 9 are arranged so that there is a substantially constant inductive coupling between them. Whilst this is not essential, this does reduce the processing required to determine the angular position of the resonator PCB and hence the angular position of the rotatable shaft 5. The sensor coils 25 and the resonator coil 9 are spatially arranged on their respective PCBs so that the inductive coupling between them varies with the angular position to be sensed.

In operation, an AC excitation signal is applied to the excitation coil 23. This causes the excitation coil to generate an excitation magnetic field that couples with the resonator coil 9 and causes the resonant circuit 10 to resonate. To achieve the most efficient energising of the resonant circuit 10, the fundamental frequency of the excitation signal should be matched with or close to the resonant frequency of the resonant circuit 10. Once powered to resonance by the excitation magnetic field, the resonant circuit 10 generates its own AC magnetic field in response. This resonator magnetic field couples into the sensor coils 25. In this embodiment, the sensor coils 25 are patterned so that the coupling of this resonator field with the sensor coils 25 varies with the angular position of the target 3 relative to the sensor coils 25. In this embodiment, the conductor tracks on the sensor PCB 1 that form the first sensor coil 25-1 will be referred to as a COS sensor coil 25 as the inductive coupling between the resonant target 3 and that sensor coil 25-1 varies with the cosine of the angle to be measured; and the second sensor coil 25-2 will be referred to as a SIN sensor coil 25 as the inductive coupling between the resonant target 3 and that sensor coil 25-2 varies with the sine of the angle to be measured. Various different conductor track patterns can be used to provide this sine and cosine variation. In addition, the conductor track pattern that defines the resonator coil 9 is also spatially patterned to improve the inductive coupling between the resonant circuit 10 and the sensor coils 25. More detail of the sensor track patterns used and the resonator coil track patterns used will be given later.

As a result of the magnetic fields generated by the resonant circuit 10 coupling back into the sensor coils 25, an EMF (Electro-Motive Force) is induced in the COS sensor coil 25-1 and the SIN sensor coil 25-2, whose amplitudes vary with the angle to be measured. The signals induced in the sensor coils may be detected by processing electronics and converted to position using an ATAN2 calculation, as described in WO2008139216. FIG. 2b is a block diagram illustrating the main components of excitation and processing electronics 31 that can be used. As shown, the excitation and processing electronics 31 include a drive circuit 33 for driving the excitation coil 23 and detection circuitry 35-1 and 35-2 for processing the signals induced in the COS sensor coil 25-1 and the SIN sensor coil 25-2 respectively and for providing a measure (which is digitised by a respective ADC 38-1 or 38-2) of the amplitude of the sensor signals to a position calculation processor 37 (which may be a microprocessor, a Central Processing Unit (CPU) or an ASIC) which performs the above position calculation. As those skilled in the art will appreciate, in alternative arrangements, the detection performed by the detection circuitry 35 can be performed in the digital domain by the position processor 37. The excitation and processing electronics 31 also includes a digital waveform generator 39 that controls the frequency and timing of the excitation signal that is applied by the drive circuit 33 to the excitation coil 23 and the timing of when the signals from the sensor coils 25 are detected. In particular, in this embodiment, because the target 3 is resonant, the target 3 can be energised during a first time period and then after the excitation has been removed the signals from the sensor coils 25 can be detected. This is because the resonant target 3 continues to resonate after the excitation signal has been removed. This “pulse-echo” mode of operation helps to minimise errors due to direct coupling between the excitation coil 23 and the sensor coils 25.

Specifically, referring to FIG. 3, FIG. 3a shows a burst of excitation current that is applied to the excitation coil 23. Providing the excitation frequency matches that of the resonant circuit 10 (within acceptable limits), energy builds up in the resonant circuit 10 in the period labelled “generate EX waveform” in FIG. 3d. The EMFs induced in the COS and SIN sensor coils 25 build up in response, so that the amplitude of the COS and SIN EMFs builds up at the resonator's resonant frequency, as shown in FIGS. 3b and 3c. Following the end of the excitation current burst the resonant circuit 10 is no longer powered and the amplitude of its oscillations begins to decay. Therefore, as shown in FIGS. 3b and 3c, the amplitude of the EMF induced into the SIN and COS sensor coils 25 also begin to decay. During the period marked “Detect EMFs from the sensor coils” shown in FIG. 3d, the signals from the sensor coils 25 are processed to determine appropriate SIN and COS measures of the angular position. This can be done by synchronous detection as noted in U.S. Pat. No. 6,788,221, or using ADCs to directly digitize the sensor signals. In this latter case the processor 37 receives the ADC data and processes it to establish measures of sensor coil amplitudes, marked COS amplitude and SIN amplitude in FIGS. 3b and 3c. This process may include performing a discrete Fourier transform at or near the resonant frequency of the resonant circuit 10. Then in the period labelled “Calculate” in FIG. 3d, the processor 37 calculates the angular position of the resonant circuit 10 and hence the angular position of the rotatable shaft 5. When sensor signal amplitudes have quadrature sinusoidal dependence on position (as they typically do in this kind of position sensor—although they may not in all cases), an ATAN2 calculation is done to convert from the (COS amplitude, SIN amplitude) vector to the angle representing position.

The description above is a generic description of how inductive position sensors that sense the position of a resonant target work. Such resonant based position sensing systems are well known in the art and are described in the various prior art documents mentioned in the introduction of this application. The description has been included to facilitate the understanding of the context of the inventions described herein.

### Excitation Circuitry

For the best accuracy in this kind of position sensor, it is important to excite the resonant circuit 10 and detect signals from it in separate time periods as illustrated in FIG. 3d, otherwise it is not possible to prevent current flow in the excitation coil during the detection period, which will cause errors in the position calculations due to the effects of direct coupling between the excitation coil 23 and the sensor coils 25. FIG. 4 is a circuit diagram of a prior art excitation circuit that the applicant has provided.

As shown, the excitation coil 23 is driven by a half bridge MOSFET circuit comprising P-channel MOSFET QB and N-channel MOSFET QA. A capacitor C_Q is connected between the QA and QB MOSFET gates. The time constant (“T_Q”) formed by the series combination of R_DRIVEH and R_DRIVEL and C_Q is chosen to be roughly the same as the excitation waveform period T_PER (which corresponds to the reciprocal of the resonant frequency of the resonant circuit 10). Before the start of an excitation pulse, DR1 is low and DR3 is high, so that both QA and QB are off. An excitation pulse begins with the digital waveform generator 39 pulling DR1 high. This turns QA on, although the turn-on time is relatively slow due to the low-pass filtering effect of R_DRIVEL and C_Q. VREF is maintained at approximately half the excitation supply voltage VDD_EX, so the voltage across the excitation coil becomes −VDD_EX/2. C_Q starts to discharge. It will become fully discharged, for practical purposes, within a time equal to about T_PER, since time constant T_Q is similar to T_PER. DR1 and DR3 are then driven by a square wave so that their low and high periods are equal at T_PER/2, and once C_Q is discharged the circuit acts like a conventional half bridge driver.

The parallel combination of R_DRIVEH and R_DRIVEL act together with the MOSFETs' Miller Capacitances to slow down the edges of the V_EX signal, so that V_EX transitions between 0V and VDD_EX in an acceptably slow time T_SL. This slowing of edges is important in order to minimise interference emitted by the excitation coil, for Electromagnetic Compatibility Reasons (“EMC”).

At the end of excitation burst, DR1 is returned to low while DR3 remains high. R_DRIVEL is chosen to be significantly larger than R_DRIVEH, typically 5 times larger. This means the turn-off of QA is relatively slow compared to T_SL. This means that the resistance of QA increases gradually. This gradual increase helps QA absorb any residual energy in the excitation coil, in case I_EX is not quite zero. If QA transitions to high resistance too quickly, before the excitation current has decayed sufficiently, the excitation current will flow in that high resistance causing a voltage spike, and hence cause EMC issues. Resistor R_SN helps suppress transients once both QA and QB are off. Its value is relatively high, so that only a small excitation current flows in it during detection as a consequence of coupling from the resonant circuit 10 back to the excitation coil 23. This in turn keeps the disturbances between the excitation coil 23 and the sensor coils 25 to a minimum, for best sensing performance. VSUPPLY is approximately equal to VDD_EX because R_EX is relatively small. The purpose of R_EX is to prevent excess peak current draw from VSUPPY during excitation bursts. C_EXSUP is large for decoupling purposes.

The inventor has found that this circuit suffers from a major drawback, which is that much of the power provided by the incoming VSUPPLY rail is lost in the drive MOSFETs due to shoot-through current. This makes the circuit inefficient at converting supply power (the average of VSUPPLY times I_SUPPLY) into excitation power (the average of excitation coil current squared times the excitation coil's resistance). Wasted power is poor for the environment and means that a larger and more expensive power supply may be required. This is exacerbated in systems designed to run at a very high measurement rate, since supply power is proportional to measurement rate, all other things being equal.

Shoot-through current is the current that flows through both the upper and lower MOSFET devices, QA and QB in FIG. 4, when QA is switching on and QB is switching off and vice versa. The transition between on and off takes a certain minimum time, which is a characteristic of the MOSFETs. Furthermore, gate resistors (R_DRIVEH and R_DRVEL in FIG. 4) are required to achieve sufficiently slow switching in order to minimise the generation of interference, as described above. This means shoot-through current flows for longer, so losses are greater.

The inventor has designed an improved excitation circuit, which is illustrated in FIG. 5. The circuit of FIG. 5 overcomes the problems noted with the circuit shown in FIG. 4. It operates efficiently with almost zero shoot-through current while emitting no more interference than the excitation circuit of FIG. 4 and very little current flows in the excitation coil during the detection period, which would otherwise cause position calculation errors.

A more detailed description of the operation of the circuit shown in FIG. 5 will now be described with reference to the signal timing diagram shown in FIG. 6. The digital waveform generator 39 generates digital drive signals DR1 and DR3 illustrated in FIG. 6. The DR1 and DR3 waveforms are similar to the corresponding signals used in the circuit shown in FIG. 4. However, with this circuit, DR1 and DR3's active states are non-overlapping. A high signal on DR1 turns on n-channel MOSFET Q1A, and a low signal on DR3 turns on p-channel MOSFET Q1B. High pulses on DR1 are separated from low pulses on DR3 by time periods T_SL.

Note that if non-overlapping clocks were to be applied to the circuit of FIG. 4, large transient waveforms would appear across the excitation coil in the periods between one MOSFET turning off and the other turning on. Since the excitation coil 23 is an inductive load, abrupt changes in excitation coil current and changes in current I_EX are therefore not possible, so the voltage V_EX will tend to abruptly change after the turn off of one MOSFET to maintain I_EX, usually forcing one of the MOSFETs' internal reverse diodes into conduction. The combination of large transient waveforms causing interference and the conduction of poor quality MOSFET internal reverse diodes causing power loss is highly undesirable.

The circuit of FIG. 5 solves this problem by introducing a capacitor C_SL that is connected between V_EX and an AC ground potential, here 0V, under the control of a switching device, here n-channel MOSFET Q2A, which is in turn under the control of a signal DR2 generated by the digital waveform generator 39.

The excitation waveform generator activates DR2 some time after the previous detection period, or at least before a significant number of excitation edges have occurred. For simplicity it activates at EX_START in the waveforms of FIG. 6. Capacitor C_SL conducts most of the excitation coil current during the periods T_SL when both Q1A and Q1B are turned off. Since time period T_SL is relatively short, excitation current I_EX remains roughly constant during times T_SL. A constant current flowing in a capacitor causes a linearly increasing or decreasing EMF across that capacitor. So V_EX slopes up and down during times T_SL following Q1A activation and Q1B activation respectively. The value of C_SL and T_SL are selected such that V_EX reaches VDD_EX just at the time that Q1B begins to conduct, and 0V just at the time that Q1A begins to conduct. This means that both of these MOSFETs turn on at points when both the voltage across them and the current through them is zero and they turn off when the voltage across them is zero. This helps further to keep power losses to a minimum. Of course, the voltage across the switches may not be exactly zero when the switches open and close. Because of tolerances in the circuit design, close to zero in this case means that the voltage may be as much as 20% of the value of VDD_EX. The timing of the pulses on DR1 and DR3 are, however, set when it is expected that the voltage across the switches will be zero. That is when the voltage on the source terminal of the switch is expected to be the same as the voltage on the drain terminal of the switch or vice versa.

The value of C_SL is relatively small compared to a capacitor value that would be needed to resonate with the excitation coil at the target's resonant frequency, because T_SL is relatively short compared to T_PER/2 (T_SL will typically be between 0.5% and 8% of T_PER). This means that the resonant frequency of the excitation coil 23 together with C_SL is much higher than the resonant frequency of the resonant circuit 10, typically between 1.5 and 6 times higher.

Another reason to keep T_SL relatively small, and hence C_SL small, is that it makes the system less sensitive to changes in the inductance of the excitation coil 23. It is preferable that the same electronic circuitry be able to drive different sensor PCBs 1 and hence different excitation coils 23, and there are constraints in the excitation coil design process for different sensors that tend to make achieving a specific constant excitation coil inductance value across a range of sensor designs difficult. If C_SL and T_SL are relatively small then the effect of inductance variation between different sensor designs is a relatively small departure from the ideal duration of the positive or negative going slope on V_EX when both Q1A and Q1B are off. Since T_SL cannot in general be exactly matched to each sensor and should ideally be a constant value for ease of design, a small nominal value of T_SL results in a small time difference between T_SL and the time it actually takes V_EX to transition between 0V and VDD_EX and vice versa. This in turn means the minimum of departure between ideal system behaviour and the extremes of operation associated with extremes of excitation coil inductance.

Note that the first and last pulses on DR1 are shorter than other pulses, which have duration (T_PER/2−T_SL). These shorter pulses typically have duration between T_PER/8 and T_PER/4, depending on excitation coil Q-factor. The reason is that I_EX has to transition half as far in current (I_PK) during these shorter pulses than it does for longer pulses in between (2×I_PK). Since the slope rate is roughly the same in all cases (rate of change of voltage=VDD_EX/2 divided by the excitation coil inductance), the first and last pulses should be shorter if the excitation current is to reach its desired peak value following the first pulse and zero after the last pulse.

Note also that the average V_EX voltage of the waveform shown in FIG. 6 is VDD/2, across the period when it is actively driven high or low by MOSFETs Q1B or Q1A respectively of FIG. 5. Since the excitation coil 23 is primarily an inductor with a small series resistance, the average voltage across it will be close to zero. Hence the voltage at VREF will tend to equal VDD_EX/2, even if VREF is not actively driven to that potential by other circuitry. In fact, by selecting a suitably large value of decoupling capacitor C_B connected between VREF and 0V, VREF can be maintained at approximately VDD_EX/2 by the action of the MOSFETs alone. This VREF potential is maintained after the end of the excitation period, “EX_END” of FIG. 6, since Q1A and Q1B are off and C_B is relatively large. So VREF may also be used as a mid-rail reference voltage for the sensor coils COS and SIN, so that the average voltages at their COSA and SINA terminals are at VREF as illustrated in FIGS. 3b and 3c.

The digital waveform generator 39 pulls DR2 low around the end of the excitation period, EX_END. This turns off Q2A, so that C_SL is no longer connected between 0V (or other AC ground potential) and V_EX. The same low signal on DR2 also turns on Q2B, which connects C_SL to VDD_EX through R_D instead.

Around the same time the digital waveform generator 39 drives out a final short active pulse on DR1, turning on Q1A. The duration of this pulse is intended to drive excitation current I_EX to near zero. Once Q1A is off at the end of this active period on DR1, excitation current flows only through C_SL and R_D. These components form a heavily damped LCR resonant circuit together with the excitation coil's inductance and resistance, so that any residual excitation current falls rapidly to zero and transients are kept to a minimum.

The digital waveform generator 39 triggers the detection process a time T_EX-RX after EX_END, so that the detection process only begins once transients will have sufficiently decayed so that they do not influence detection results significantly.

Note that Q2B remains on and R_D and C_SL remain connected to V_EX during detection. However, the LCR circuit that they form has a resonant frequency well above the resonant frequency of the resonant circuit 10 on the target 3 and is very heavily damped by choice of R_D, so that very little excitation current flows in the excitation circuit during detection, which would otherwise interfere with position measurements as noted above.

MOSFET gate resistors R_DR1, R_DR2 and R_DR3 slow down the transitions between MOSFET off and on and on and off states, so that MOSFET on-resistances decrease gradually during turn on and increase gradually during turn off. This helps further to decrease transients and hence interference emissions. And since Q1A and Q1B turn on and off when the voltage across them is near zero, the initial high resistance of these devices when turning on and final resistance when turning off does not contribute significantly to losses of power.

The excitation circuitry shown in FIG. 5 can be considered to comprise an impedance network that has different states or configurations that is connected to the excitation coil 23. A drive circuit provides the supply current/voltage that is applied to the excitation coil 23 via the impedance network and the digital waveform generator 39 acts as a controller that controls the drive circuitry and the impedance network to control the excitation of the excitation coil 23. During the period when excitation current is applied to the excitation coil 23, the impedance network presents a first impedance that is primarily capacitive to the excitation coil 23 (by way of the capacitor C_SL) and when the excitation current is removed from the excitation coil, the impedance network is configured to present a second impedance to the excitation coil that is much larger in magnitude (at least two times) than the magnitude of the first impedance when measured at the resonant frequency of the target (in the exemplary embodiment this is achieved by switching in the resistance R_D). Switching in resistor R_D effectively decouples the capacitor C_SL from the excitation coil 23. In one specific and non-limiting embodiment, the target resonant frequency was chosen to be 840 KHz and C_SL was chosen so that at the resonant frequency the impedance of C_SL was 57 ohms. R_D was selected to be 220 ohms which is approximately four times the impedance of C_SL at the target's resonant frequency. In this non-limiting embodiment, the excitation coil 23 was designed so that its impedance at the target's resonant frequency was 9.6 ohms, which is much lower than the impedance of C_SL at this frequency.

The different circuit configurations that the excitation circuit shown in FIG. 5 has for the different states of the MOSFET switches due to the different states of the control signals DR1, DR2 and DR3 shown in FIG. 6 are shown in FIGS. 7a to 7e.

FIG. 7a illustrates the state of the MOSFET switches when the excitation circuit is not energising the resonant circuit 10. In this stage, DR1 and DR2 are at a LOW level and DR3 is at a HIGH level. As shown, in this state, switches Q1A, Q2A and Q1B are all open and MOSFET Q2B is closed meaning that C_SL is connected on one side to VDD_EX through resistor R_D and is connected to ground through capacitor C_B and the excitation coil 23. Thus, in this state, the high valued resistor R_D has been switched into circuit with C_SL and the excitation coil. In this state, if the resonant circuit 10 is resonating, the resonator magnetic field will not couple significant excitation current I_EX into the RLC circuit formed by R_D, C_SL, the excitation coil 23 and C_B because the resonant frequency of this RLC circuit is higher than the resonant frequency of the resonant circuit 10 and is heavily damped by the high resistance value of R_D. This minimises current flow in the excitation circuit in this state.

FIG. 7b illustrates the state of the MOSFET switches when the excitation circuit is energising the resonant circuit 10, when each of DR1, DR2 and DR3 is at a HIGH level. As shown, in this state, switches Q1A and Q2A are closed and switches Q1B and Q2B are open meaning that the V_EX terminal of the excitation coil 23 is pulled to ground (0V). In this state the current flowing through the excitation coil 23 reduces until it reaches the peak negative current (−I_PK). At this point, the switches are put into the state shown in FIG. 7c in which each of DR2 and DR3 is at a HIGH level and DR1 is at a LOW level. As shown, in this state, switch Q2A is closed and switches Q1A, Q1B and Q2B are open meaning that the excitation coil's V_EX terminal is only connected to ground (0V) through the capacitor C_SL. Switching to this state when the current flow through the excitation coil 23 is at the peak negative value causes the voltage on the excitation coil's V_EX terminal (and hence the voltage across C_SL) to increase to VDD_EX.

Once the voltage on the excitation coil's V_EX terminal has reached VDD_EX, the state of the switches is changed to that shown in FIG. 7d in which each of DR1 and DR3 is at a LOW level and DR2 is at a HIGH level. As shown, in this state, switches Q1B and Q2A are closed and switches Q1A and Q2B are open meaning that the excitation coil's 23 VDD_EX terminal is maintained at the voltage VDD_EX. In this state, the current flowing through the excitation coil 23 increases until it reaches the peak positive current (I_PK) at which point the switches are put into the state shown in FIG. 7c again. Switching to this state when the current flow through the excitation coil 23 is at the peak positive value causes the voltage on the excitation coil's V_EX terminal (and hence the voltage across C_SL) to decrease to ground (0V). Thus, by constantly switching through the states shown in FIGS. 7b, 7c, 7d and then 7c again, the excitation current through the excitation coil 23 is driven in an alternating manner between I_PK and −I_PK—as shown in FIG. 6. This operation is entirely controlled by the control signals output by the digital waveform generator 39.

FIG. 7e illustrates the state of the MOSFET switches towards the end of the excitation burst, when each of DR1 and DR3 is at a HIGH level and DR2 is at a LOW level. As shown, in this state, switches Q2B and Q1A are closed and switches Q2A and Q1B are open meaning that the excitation coil's V_EX terminal is connected to ground (0V) through switch Q1A. This reduces the current flowing in the excitation coil 23 to close to zero by the time that the short pulse on DR1 goes low again at EX_END.

The excitation circuitry shown in FIG. 5 can be used in any inductive resonant position sensor where the excitation circuit is designed to energise a resonant target. It can be used in linear position sensors or rotary position sensors and can be used in any of the prior art sensor systems described in the patents and patent applications referred to above in the introduction of this patent application.

FIG. 8 shows preferred excitation and processing circuitry when the excitation circuitry shown in FIG. 5 is implemented in a system having four sensor coils 25-1 to 25-4. In this case, sensor coils 25-1 and 25-2 provide “fine” position resolution and sensor coils 25-3 and 25-4 provide “coarse” position sensing resolution. More specifically, sensor coils 25-1 and 25-2 provide COS and SIN position sensing information that repeats multiple times per revolution of the shaft 5 and the coarse sensor coils 25-3 and 25-4 provide COS and SIN position sensing information that can resolve the position ambiguity in the position information determined from the sensor coils 25-1 and 25-2.

In this case the detection performed by the detection circuitry 35 shown in FIG. 2b is performed by the processor 37. The signals from the sensor coils 25-1 to 25-4 are passed through two stages of passive RC filtering, for example formed by components R_MCOS, C_MCOS, R_FCOS and C_FCOS in the case of the signals from the COS coils 25-1 and 25-3 and R_MSIN, C_MSIN, R_FSIN and C_FSIN in the case of the signals from the SIN coils 25-2 and 25-4. These components form an anti-alias filter for the ADCs 38, to minimise the effect of pick-up of interference at higher frequencies than the resonator's resonant frequency on the outputs of the ADCs. Note that these low-pass filters preserve the DC bias voltage, so that the average voltage at the COS1 ADC input equals the average voltage at COSA, which will equal VREF which is approximately VDD_EX/2 as previously discussed. Therefore, the ADC inputs are biased to VDD_EX/2, at approximately mid-rail which yield the maximum possible headroom for coil AC signals to transition both positively and negatively relative to VREF, before being clipped if outside rail voltages 0V and VSUPPLY.

The digitised signals from the fine sensor coils 25-1 and 25-2 are then processed to determine high resolution but ambiguous position information for the position of the target 3 relative to the sensor board 1. The digitised signals from the coarse sensor coils 25-3 and 25-4 are processed to determine coarse position information which can be used to resolve the position ambiguity associated with the fine position measurements. The resulting position information is then provided to a host computer system (not shown) via an interface 41.

### Alternative Excitation Circuitry

The digital waveform generator 39 described above generated waveforms with a fixed T_SL period. This may not be the ideal time delay due to component tolerances. Another approach is illustrated in FIG. 9. In this circuit, the V_EX signal is sensed and fed back into the digital waveform generator's V_EXSENSE terminal. Analog comparators 43-1 and 43-2 inside the digital waveform generator 39 compare V_EXSENSE with 0.9×VSUPPLY and 0.1×VSUPPLY respectively. Q1A is switched on at EX_START as before, and the times at which Q1A and Q1B subsequently switch off are set digitally as before, depending on a pre-set first pulse width on DR1 and excitation period T_PER. However, the outputs of the comparators 43 are used to time the turn on of Q1A and Q1B. Each time Q1A is turned off (DR1 goes low) the excitation waveform generator waits until a comparator signal indicating V_EXSENSE has exceeded VSUPPLY×0.9, and then turns on Q1B by pulling DR3 low. Each time Q1B is turned off (DR3 goes high) the excitation waveform generator waits until a comparator signal indicating V_EXSENSE has gone below VSUPPLY×0.1, and then turns on Q1A by driving DR1 high. This proceeds until the beginning of the last high going pulse on DR1, which this time coincides with the last positive going pulse on DR3 as before. This approach ensures that the turn on of MOSFETs actually occurs at an appropriate V_EX voltage when the sloping portion of the waveform is close to the relevant supply rail. The exact value of the compare voltages (here 0.1× and 0.9×VSUPPLY) are chosen to ensure that MOSFETs turn on with low resistance at the point their drain to source voltage is near zero, considering that there is a delay between DR1 and DR3 going active and their respective MOSFETs actually becoming fully turned on. This approach allows the excitation waveform generator to adapt to different values of excitation inductance and capacitance C_SL, maintaining optimum efficiency and low emissions in spite of high variability in those values.

In the system described above, the resistor R_D was connected to VDD_EX by a switch Q2B that switches on at the same time as Q2A switches off, both being under the control of DR2. This approach is relatively simple because it allows both Q1 and Q2 to be the same type of dual MOSFET device, which reduces the complexity of the Bill of Materials used to construct the circuitry. However, this is not essential. R_D can be connected to any suitable AC ground potential including VREF or 0V. In fact, it is not essential that R_D be switched at all, it just saves a small amount of power by preventing current flow in R_D during excitation. If a switch is omitted it is best to connect R_D between V_EX and VREF, so that its presence does not upset the VREF bias voltage.

It is convenient to use MOSFETs as switching devices for the circuitry described above, since they are relatively low cost and inexpensive and conduct current well in both directions. Bipolar transistors can replace MOSFETs, providing high-quality Schottky diodes are placed between their collectors and emitters to conduct current when reverse current would otherwise flow.

If a higher excitation drive voltage is required, then a full bridge circuit such as the one illustrated in FIG. 10 may be used. Its design and operation are similar to the circuitry of FIG. 5. The digital waveform generator 39 generates the same DR1 and DR3 signals (as shown in FIG. 11). The digital waveform generator 39 also generates their complements, DR5 and DR4 respectively, which are used to drive Q4B and Q4A gates respectively. When DR1 is high and DR5 is low, and DR3 is high and DR4 is low, the excitation coil 23 is connected across VDD_EX such that V_EX=−VDD_EX. When DR1 is low and DR5 is high, and DR3 is low and DR4 is high, the excitation coil is connected across VDD_EX such that V_EX=VDD_EX. All switches are off when DR1 and DR4 are low and DR3 and DR5 are high. This all-off state is used during excitation to allow the V_EX voltage to switch polarity at a controlled rate due to excitation current I_EX flowing in the two C_SL capacitors, in a similar way as the half bridge circuit described above. The all-off state is also used after EX-END and during detection, to minimise current flow in the excitation coil during detection.

### Digital Waveform Generator

As is clear from the above description, the digital waveform generator 39 controls the entire excitation process of the excitation coil 23 using the control signals DR1, DR2 and DR3 (and DR4 and DR5 in the case of the full bridge driving of FIGS. 10 and 11). The digital waveform generator 39 may be implemented using standard microcontroller peripherals, for ease of implementation and low cost. Error! Reference source not found. 12 outlines one example implementation of the digital waveform generator 39—many other examples will be immediately apparent to those of ordinary skill in the art. A clock input to the digital waveform generator 39 is at a frequency much higher than the resonator frequency of the target 6, in this example between 100 and 500 times higher.

Before each measurement the processor writes a number of parameters to registers that control excitation waveform generator bocks. N_FL is the duration of the first and last pulse on DR1 in clock ticks. PWMPER is the period of the excitation waveforms in clock ticks that is required to generate the period T_PER of the excitation waveform shown in Error! Reference source not found. 6. PWMH1 and PWML1 control the time at which DR1 goes high and then low following the first low edge on DR1, and every multiple of PWMPER clock ticks after that. The processor sets PWMH1 to PWMPER*0.5-N_SL, where N_SL is the number of clock ticks representing the period T_SL. That way, the high time on DR1 following the first pulse is 50% of its period minus the T_SL period. PWMH2 and PWML2 control the time at which DR3 goes high and then low following the first low edge on DR1, and every multiple of PWMPER clock ticks after that. PWML2 is set to N_SL and PWMH2 is set to PWMPER*0.5, so that the low times on DR2 are also 50% of the period minus T_SL and low periods on DR3 are separated from high periods on DR1 by T_SL. N_STOP controls the number of low periods on DR3 that are required, which is very roughly resonator Q-factor divided by pi for maximum efficiency or slightly greater to energise the resonator more fully before EX_END. N_RXDEL is the time required between the last edge on DR3 and the beginning of detection, which equals T_EX-RX plus T_SL plus the last DR1 pulse width, converted to clock ticks.

The processor 37 starts a measurement by activating a Start signal, which could alternatively be generated by a measurement interval timer if measurements are required at a continuous fixed rate. This starts a timer 80 used to time the first and last pulses on DR1, which generates an Out signal that goes high while the timer is running. DR1 is generated by an OR gate 81 with one input connected to this Out signal, so that it goes high for the required time period. DR2 is generated by the flip-flop 79, which is set when it receives the Start signal at EX_START and is cleared by counter 85 when DR2 is to be made low again.

Pulse Width Modulation (PWM) generators 83-1 and 83-2 are started when timer 80 stops. Each PWM generator 83 generates one high edge and one low edge on its output, repeating with a period controlled by PWMPER in clock ticks. The high edge occurs PWMH clock ticks from the start of each period, and the low edge occurs PWML clock ticks from the start of each period. The PWM generators 83 both start on the first negative edge of DR1 and stop under the control of a counter 85 described below. As noted above, the processor 37 preconfigures PWMH and PWML for each PWM generator 83 so as to generate the DR1 and DR3 waveforms required up until the last full-width pulse on DR1.

The counter 85 connected to the DR3 output counts DR3 low periods at its clock input and when this number equals N_STOP it activates its output. This is used to trigger the timer 80 again, which generates the last pulse on DR1 in the same way as the first pulse. The output of counter 85 is also used to stop both PWM generators 83 so that they don't activate DR1 and DR3 any more until the next Start signal and to set DR2 low again through the flip-flop 79. The counter 85 is also used to time an RX_TRIG signal used to start detection, for example triggering a number of regularly spaced ADC conversions.

If the digital waveform generator 39 is implemented inside a microcontroller then the exact choice of peripherals, their cross connections and controls will depend on what is available in that particular microcontroller. An alternative arrangement available in different microcontrollers is based around the use of digital compare modules, which set and reset digital outputs when a master timer value reaches pre-set thresholds. Those pre-set thresholds can be obtained by the peripheral directly from the processor's memory, and those memory locations can be incremented each time an edge is activated or reset. According to this alternative approach, the processor preloads the relevant memory locations with the times at which the digital compare module is required to change the state of its digital outputs. The processor computes these timings so as to generate the waveforms of FIG. 6 or 11. The digital waveform generator 39 may alternatively be implemented using configurable digital logic blocks inside an FPGA, for example coded in VHDL or Verilog programming languages, or in a dedicated digital or mixed signal integrated circuit. The applicant makes and sells (separately from other components such as the sensor boards or the drive circuitry) integrated circuit chips that include the digital waveform generator 39 as well as the ADC circuits 38 and the processor 37. This chip is illustrated by the dashed box shown in FIG. 8 that is labelled “Resonant Inductive processor IC”.

### Sensor PCB

FIGS. 13a to 13d illustrate the four layers of the sensor PCB 1 used to implement the sensor coils and the excitation coil according to an embodiment. Each of these figures illustrates the conductor (typically copper) traces on its respective conductor layer. The circles mark the location of vias used to make connections to conductors on other layers. The conductor layers are numbered 1 to 4, with layer 1 corresponding to the top layer of the sensor PCB 1 that will be closest to the resonator PCB 6 and layer 4 corresponding to the bottom layer of the sensor PCB 1 that will be furthest from the resonator PCB 6.

FIG. 14a is a plan view of the conductors of the sensor PCB 1 that are connected together to define the fine COS coil 25-1, COSA. FIG. 14b is a plan view of the conductors of the sensor PCB 1 that define the fine SIN coil 25-2, SINA. FIG. 14c is a plan view of the conductors of the sensor PCB 1 that are connected together to define the coarse COS coil 25-3, COSB. FIG. 14d is a plan view of the conductors of the sensor PCB 1 that define the coarse SIN coil 25-4, SINB. FIG. 14e is a plan view of the conductors of the sensor PCB 1 that define the excitation coil 23, EX.

The conductor tracks that form the fine COSA sensor coil 25-1 are run in six sets of loops around the sensor PCB 1, with adjacent sets of loops being wound in the opposite direction (in a repeating “figure of 8” arrangement). This alternating winding direction of adjacent sets of loops is represented in FIG. 14a by the “+” and “−” signs in the middle of each set of loops. As a result, the sensitivity to AC magnetic field of the COSA sensor coil 25-1 varies sinusoidally with angle, with three sinusoidal repeats per complete 360° of the target 3.

The conductor tracks that form the fine SINA coil 25-2 are also run in six sets of loops around the sensor PCB 1, with adjacent sets of loops being wound in the opposite direction (in a repeating “figure of 8” arrangement). As a result, the sensitivity to AC magnetic field of the SINA sensor coil 25-2 also varies sinusoidally with angle, with three sinusoidal repeats per complete 360° of the target 3. The sets of loops of the SINA sensor coil 25-2 are, however, rotated physically by 30° relative to the sets of loops of the COSA sensor coil 25-1 such that its inductive coupling is in spatial phase quadrature (90° electrically out of phase) with that of the COSA sensor coil 25-1.

The conductor tracks that form the COSB sensor coil 25-3 are run in two sets of loops, with adjacent sets of loops being wound in the opposite direction (in a “figure of 8” arrangement). As a result, the COSB sensor coil 25-3 has a sensitivity to AC magnetic field that varies sinusoidally with angle, with one sinusoidal repeat per complete 360° rotation of the target 3. The positive peak in sensitivity occurs for a source of AC field between the sensor coil's outer and inner diameters at the right hand side of the sensor 1 (as drawn). The negative peak occurs at the left hand side (as drawn).

The conductor tracks that form the SINB sensor coil 25-4 are arranged in a similar way to the tracks of the COSB sensor coil 25-3 but rotated physically by 90°. As a result, the inductive coupling between the target 3 and the SINB sensor coil 25-4 is in spatial phase quadrature (90° electrically out of phase) with that of the COSB sensor coil 25-3.

The sensor PCB 1 also includes an excitation coil 23 comprising multiple turns of conductor that run close to the outer perimeter of the sensor coils 25. This arrangement is designed to generate an excitation magnetic field that will energise the resonant circuit 10 mounted on the resonator PCB 6 regardless of the position of the target 3.

Unlike U.S. Pat. No. 6,522,128, the excitation coil 23 does not fully coincide or overlap with the radial spokes of the sensor design. Some turns of the excitation coil 23 weave around the sensor's outer vias, primarily on layers 3 and 4. This is because the area of the radial spokes of the fine sensor coils primarily on layer 2 shown in FIG. 13b are coincident with portions of the coarse sensor coil built on layer 1 illustrated in FIG. 13a. There are four almost identical coarse coil portions on this layer, each spanning just under approximately a quarter of a circle. The right and left hand of these layer 1 coil loops are connected in series with the right and left hand portions of the remainder of the coarse COSB coil 25-3 mainly implemented on layer 4 shown in FIG. 13d. These connections are made using vias located within the radial spokes of layer 2 copper. The upper and lower of these layer 1 coil portions are connected in series with the remainder of the coarse SINB coil mainly implemented on layer 3 shown in FIG. 13c. The additional loops of coarse coils on layer 1 helps to increase coarse coil signal levels. Since they are implemented on the same physical copper layer, unlike the remainder of each copper layer, signal levels induced by the resonator coil 9 are more equal. Signal levels induced in layer 4's portion of the coarse COSB sensor coil 25-3 will tend to have a smaller peak amplitude than those induced in layer 3's coarse SINB sensor coil 25-4 portion due to the greater distance between the resonator coil 9 and layer 4, which reduces coarse sensing accuracy somewhat. However, implementing some of the two coarse coils 25-3 and 25-4 on the same PCB layer (in this case layer 1), especially one closest to the resonator coil 9, tends to reduce this error by making peak amplitudes more similar.

Note also that the inner vias of the sensor board design, those inside the inner radius of the radial spokes of the fine sensor coils (closest to the shaft 5 in use), are packed together as closely as possible, bearing in mind that conductor widths and gaps between conductors have been minimised consistent with chosen design rules. The loops of the coarse COSB sensor coil 25-3 implemented on PCB layer 4 shown in FIG. 13d weave in between some of these inner vias, in order to maximise coil lobe areas and hence signal levels in the coarse COSB coil. The same is done with the coarse SINB loops on sensor PCB layer 3 shown in FIG. 13c. Specifically, these inner vias are generally arranged in at least two rings around the central hole 8 of the sensor PCB 1, and conductors forming part of the coarse COSB sensor coil 25-3 and conductors forming part of the coarse SINB sensor coil 25-4 pass in the space between these at least two rings of vias.

The left and right hand lobes of the COSB sensor coil 25-3 have to be connected together and in opposite directions. This is done with conductors and vias between the inner and outer spoke radii. Connecting vias fit between gaps in the radial spokes, whose angular positions have been optimised for best accuracy, in particular to minimise sensitivity to fields whose periodicity is 3 times that of the fine sensor coils (“3rd spatial harmonic sensitivity”). The upper and lower SINB coil 25-4 lobes are connected together by similar traces and vias but rotated by 90°.

The fine sensor coils 25-1 and 25-2 are largely formed using twelve repeating groups of conductors and vias on layers 1 and 2 (shown in FIGS. 13a and 13b) with equal spacing between groups of 30°. Portions 60° apart are used to construct opposite polarity loops of the same sensor coil, to avoid errors associated with + and − lobes being non-equal. Portions 120° apart form the 3 lobes of each fine sensor coil, either positive or negative, to ensure a pure sinusoidal sensitivity with 3 repeats per circle, for best accuracy. The SINA coil 25-2 is built to the same design as the COSA sensor coil 25-1 except rotated 30°. Since the COSA and SINA coils are largely built on exactly the same layers and are almost identical except for that rotation, the sensor has very little gain mismatch between the COS and SIN coils, which is important for minimising errors in reported position.

The exact path of all sensor and target conductors will generally be established by detailed simulation and optimisation of the conductor tracks on the sensor PCB 1 and the conductor tracks on the resonator PCB 6 working together.

### Resonator PCB

The sensor PCB 1 is suited to operation with a relatively moving target built from the resonator PCB 6 illustrated in FIG. 15. In this embodiment, the resonator PCB 6 has six layers-shown in FIGS. 15a to 15f. Each layer is also numbered 1 to 6, with layer 6 being closest to the sensor PCB 1 in use. Layers 1, 2, 5 and 6 each carry conductor tracks that define three sets of loops that are evenly spread around the resonator PCB 6. The three sets of loops on these four layers are all connected together at the vias (represented by the circles) so that current flows in the same direction around each set of loops. The number of sets of loops (in this case 3) has been chosen to match the number of repeats of the fine sensor coils 25-1 and 25-2. In this way, the spatial periodicity of the magnetic field that will be generated by a current flowing in these loops will match with the sensitivity to AC magnetic field of the fine sensor coils 25-1 and 25-2. Resonator PCB layers 3 and 4 also carry sets of loops—in this case two sets of loops which are circumferentially spaced apart by 180 degrees. These two sets of loops are connected together so that current flows in the opposite direction within the two sets of loops. As a result, these two sets of loops couple well both to the coarse sensor coils 25-3 and 25-4 and to the fine sensor coils 25-1 and 25-2.

All of the sets of loops on the six layers of resonator PCB 6 are connected together to form the resonator coil 9. The two ends of the resonator coil 9 terminate at the connection pads C1 and C2 shown on the left hand side of layer 1 shown in FIG. 15a and to which the capacitor 7 is connected to form the resonant circuit. FIG. 16a shows how the different sets of loops are connected together and illustrates the direction of current flow in each set of loops. As shown the current flow in the set of loops labelled “Lobe 3” is opposite to the direction of current flow in the other sets of loops labelled “Lobe 1”, “Lobe 2” and “Lobe 4”. More specifically, starting from point A in FIG. 16a (corresponding to one connection pad for the capacitor 7), current flows along the following path:
From C1 and C2 right hand terminals on layer 1 to via L
From via L on layer 2 to via E
From via E on layer 5 to via G
From via G on layer 6 to via K
From via K on layer 5 to via M
From via M on layer 6 to via C
From via C on layer 1 to via F
From via F on layer 2 to via J
From via J on layer 4 to via D
From via D on layer 3 to via H
From via H on layer 1 to C1 and C2 left hand terminals

Resonator current flowing in the conductors of layers 1, 2, 5 and 6 generates a magnetic field which spatially varies with angle (here denoted theta) around the central axis of rotation in a cyclic manner repeating three times per revolution as illustrated in FIG. 16b. The vertical axis is magnetisation in arbitrary units. The field from the conductors of layers 1, 2, 5 and 6 has a primary spatial component of magnetic field varying at three times theta. Due to the rotational symmetry of the design, especially when considering layers 1 and 2 and layers 5 and 6 in pairs, there are no components with spatial frequency two times theta, or any other even multiple of theta. The only significant harmonics are at three times odd multiples of theta such as 9, 15 and so on. The unwanted effect of these higher harmonics on accuracy is minimised by the details of the design of the sets of loops on those layers, including their angular spans (for example AL1 in FIG. 15a on layer 1), conductor radii and spacings and the number of coil turns. This means errors are kept to a minimum, especially if the sensor and target are tilted and misaligned relative to one another, as noted in U.S. Pat. No. 6,534,970.

The magnetic field from conductors of layers 1, 2, 5 and 6 also has a zeroth spatial frequency component, corresponding to field that is uniform with angle around the central rotation axis. This allows the uniform excitation coil 23 on the sensor PCB 1 to power the resonant circuit 10 irrespective of angle.

Resonator current flowing in the conductors of layers 3 and 4 generates a magnetic field which spatially varies around the central axis of rotation once per revolution as illustrated in FIG. 16c. There is an axis of symmetry in the designs of layers 3 and 4, in this case the diameter of the resonator PCB that is vertical as drawn and lying in the plane of the PCB, such that the set of loops on layers 3 and 4 to the right carry current and generate field shapes that are almost exactly equal and opposite to the currents and field shapes generated by the set of loops on the left of layers 3 and 4. This anti-symmetry is not present in the resonator coils used in the device described in U.S. Pat. No. 6,534,970.

It should be noted that the right hand set of loops on layers 3 and 4 are positioned at approximately the same position on the PCB (at the 3 o'clock position) and overlap with the right hand sets of loops on layers 1, 2, 5 and 6 that are shown at the same 3 o'clock position. In this exemplary embodiment, there is not an exact overlap between the sets of loops at this position. This can be seen by comparing the angle AL3 shown in FIG. 15c with the angle AL1 shown in FIG. 15a. As can be seen angle AL3 is greater than AL1. The angular spans AL1 and AL3 are determined in an optimisation process to minimise unwanted harmonics in the magnetic field that is generated by the resonator.

The magnetic fields generated by currents flowing in the conductors of layers 3 and 4 are illustrated in FIG. 16c. If a resonator were constructed using their right hand portions as drawn alone, the system would report a certain angle A1 when the actual angle is A, and signal level M1. If a resonator were constructed using only the left hand portions as drawn, carrying the same amplitude and phase of resonator current, the system would report an angle A2 when the actual angle is A, and signal level M2. When there is no lateral or tilt misalignment between sensor and target, A1 and A2 are equal. This is because the matching sensor coils 25 have an odd number of coarse and fine periods around a circle, so a magnetic field from target portions 180° apart will cause sensor signals to flip polarity. The fact that the right hand set of loops of layer 3 and 4 of the resonator PCB 6 generates a field that is equal and opposite to the left hand set of loops means that sensor signals from the left hand portion are flipped in polarity again relative to those from the right. So the overall effect of the left hand set of loops being 180° displaced from the right hand set of loops and carrying equal and opposite current is that the reported position remains the same, providing tilt and misalignment are zero.

If the resonator PCB 6 and the sensor PCB 1 are laterally misaligned, this no longer holds. For example if the resonator PCB 6 is moved upward relative to a sensor underneath, the angle A1 will increase and A2 will decrease. The amount by which each increases or decreases will tend to be the same, at least for small lateral alignments, so that their average will equal the average of A1 and A2 without lateral misalignment. In other words, the system will be immune to lateral misalignment, at least to some extent.

The sensor coils effectively add together angle contributions from the left hand set of loops and the right hand set of loops. This means that the system's reported position output will be the average of A1 and A2 weighted by the amplitudes M1 and M2 respectively. This will only equal the average of A1 and A2 if M1 and M2 are approximately equal. So, in order to obtain best immunity to lateral misalignment, M1 and M2 should be made equal.

Note that this applies to both fine sensor coils (here with 3 repeats around a circle) and coarse sensor coils (with 1 repeat).

The design of layers 3 and 4 of the resonator PCB 6 is optimised like layers 1, 2, 5 and 6 to minimise unwanted spatial harmonics such as the 9th spatial harmonic, which would otherwise introduce errors in the position calculations. It is also optimised to maximise the level of the 3^{rd} spatial harmonic, which matches well with the sensitivity of the fine sensor coils 25-1 and 25-2. The main parameters that are changed for optimisation are angle AL3 (shown in FIG. 15c) and conductor spacings and radii. Note that angle AL3 is not optimised for maximum coupling to the coarse sensor coil, because the sensor system's performance comes mainly from fine signal levels and coarse signal levels can be allowed to be smaller.

U.S. Pat. No. 6,534,970 describes its FIG. 8a as including a DC component to its field, by which it means a component that is uniform with angle. Furthermore, it notes that distortions will occur in the coarse coil due to tilt or offset due to this DC component, because its harmonic number of 0 differs from the coarse coil harmonic number of 1 by 1. By making the left and right hand sets of loops of resonator PCB layers 3 and 4 anti-symmetric, this DC component is eliminated, because whatever uniform component exists to the right will have an equal and opposite component to the left, and the two will cancel. By eliminating this uniform, DC component, to the fields generated by the current flowing in the resonator PCB's layers 3 and 4 we have eliminated much of the error in the measurement of coarse position associated with misalignment and tilt.

U.S. Pat. No. 6,534,970 described coarse coil signals as only being used to resolve the phase ambiguity of the phase measurements form the fine sensor coils, which is equivalent to saying the coarse coils are used to tell which fine period the target's right hand lobe is nearest to. U.S. Pat. No. 6,534,970 teaches that the effect of misalignment on coarse sensor coil readings is insignificant, because the accuracy with which this ambiguity must be resolved is not as great as the accuracy required from the fine sensor coils. Nevertheless, it is important, otherwise the amount of allowable tilt and misalignment will be limited. This is especially the case for small sensors, where immunity to lateral misalignment of 1 mm is preferred due to stack-up of several mechanical tolerances each perhaps on the order of 0.2 mm. In the case of a small sensor such as one whose outer coil conductors have an outer radius of 12 mm, 1 mm is a very significant amount, and the combination of tilt, misalignment and other errors will eat significantly into error margin, putting the determination of the correct fine period at risk.

Note that each of the layers of FIG. 15 includes a right hand set of loops (at the 3 o'clock position as drawn) that either spirals inward or outward. This means that each one individually does not quite have top to bottom symmetry as drawn, and the result is the introduction of a small level of spatial components of magnetic field having an even number of repeats around a circle, including 2nd and 4th harmonic components. Since the fine sensor coil has 3 repeats per circle, differing from these harmonic components by 1, according to U.S. Pat. No. 6,534,970 there will be errors introduced to position readings that increase linearly with misalignment and tilt. These are eliminated by arranging coils in adjacent pairs, so that coil lobes on one layer that spiral inward are matched by a similar coil on an adjacent layer that spirals outward. By placing these similar coil portions on adjacent layers, errors caused by even spatial harmonics are largely eliminated, because their effects as seen by the sensor will be equal and almost opposite. They are not quite opposite because the adjacent layers do not quite have zero spacing from one to another, but the cancellation effect is largely effective given typical layer separations on the order of 0.12 mm.

The resonator coil 9 formed by the sets of loops shown in FIG. 15 will have a much greater Q-factor than those described in U.S. Pat. No. 6,534,970, making them suitable for electronic processing illustrated in FIG. 5 which yields greater accuracy than using continuous excitation and detection. The integrated detected signal level will be much greater due to the greater amplitude of resonator signal at the point that detection starts, and a greater duration of signal. These improvements arise fundamentally from the use of a greater mass of copper in the resonator coil 9, due to implementation on multiple PCB layers. It is also important that PCB trace widths remain relatively narrow, around 0.2 mm or less for operation around 1 MHz, otherwise the AC skin effect resistance of the coils becomes large causing significant Q-factor reduction. That is why multiple loops of narrow conductors are used rather than a smaller number of conductors having a greater width. The number of turns on each lobe on each layer should be high to ensure there is as much mass of copper as possible for high Q-factor, up to a limit where additional turns introduce more resistance and have too small a coupling area to significantly increase inductance.

In use, sensor PCB layer 1 is oriented so that it is adjacent the resonator PCB layer 6. The resonator PCB layer 1 includes one or more tuning capacitors that form the resonant circuit with the inductance of the printed coils, and this capacitor would otherwise prevent the two PCBs from approaching each other closely for maximum signal level. Layers 1 and 2 of the sensor PCB 1 carry most of the conductors forming the fine sensor coils 25-1 and 25-2 whose signal level should be maximised, which is why they are the layers positioned closest to the resonator PCB 6.

Another important design feature of the resonator coil 9 is to minimise the coupling between the resonator coil 9 and any metal on the inside of the circuit board-such as a steel shaft 5 on which the resonator PCB 6 is mounted for rotation. This is achieved by balancing (by which we include substantially balancing) positive field and negative field that couples with the shaft 5. Specifically, referring to FIG. 16a, current flowing in lobes 1, 2 and 4 all create a negative field in the through hole 8 of the resonator board 6 (where the shaft 5 is located). This negative field is balanced to some extent by the positive field generated in the through hole 8 of the resonator board 6 by current flowing in lobe 3. The rest of the balance is created by current flowing near the inside diameter of the sensor PCB in connecting conductors that form part of three anticlockwise loops that extend around the through hole 8 of the resonator board 6 which also creates a positive field in the through hole 8 of the resonator board where the shaft 5 is located. The conductors forming these effective anticlockwise loops are most evident in regions 51 and 53 illustrated in FIGS. 15a to 15f. Region 53's 3 loop portions are formed by conductor traces shown inside that marked region in FIG. 15a, FIG. 15c and FIG. 15e. Region 51's 3 loop portions are formed by conductor traces shown inside that marked region in FIG. 15b, FIG. 15d, FIG. 15e and FIG. 15f. However, the three anticlockwise turns around the through hole 8 also effectively continue (although are not defined by physical conductors) through lobes 1, 2, 3 and 4. Specifically, if one were to track the conductors shown in the different layers of the resonator PCB as shown in FIGS. 15a to 15f, one would find that there are 42 conductors on the right hand side of lobe 1 as drawn (with current flowing up the page) and there are 39 conductors on the left hand side of lobe 1 as drawn (with current flowing down the page). This difference in number of conductors on the inside of lobe 1 is due to these effective three anticlockwise loops around the through hole 8—which effectively cancel out three inside conductors of lobe 1 as they carry current in the opposite direction to the direction of current flow in these three anticlockwise loops around the through hole 8. Similarly, there are three fewer conductor turns on the inside (closest to the through hole 8 of the resonator PCB) of lobes 2 and 4 than there are on the outside of lobes 2 and 4. With regard to lobe 3, current flows in the opposite direction in this lobe compared to the other lobes and so there are 3 additional conductors on the inside (closest to the through hole 8 of the resonator PCB) than there are on the outside of lobe 3 (because the three additional anti-clockwise turns around the through hole 8 carry current in the same direction as the inner turns of lobe 3). One of these extra turns is formed by conductors of layers 3 and 4 shown in FIGS. 15c and 15d. The other two are on layers 1 and 2 shown in FIGS. 15a and 15b. In this way, positive and negative field generated by the PCB resonator is balanced in the through hole 8 of the resonator PCB at the location of the shaft 5—which minimises coupling between the resonator 10 and any metal in or around the shaft.

### Second Embodiment

FIGS. 17a to 17d illustrate conductor layers 1, 2, 3 and 4 of an alternative sensor PCB 1′, together with vias drawn as circles like before. This sensor PCB 1′ has a larger diameter than the sensor PCB 1 shown in FIG. 13. It is therefore possible to fit more fine sensor periods (in this case 5 periods) around the rotation axis, and each fine sensor coil 25-1 and 25-2 has 4 turns instead of 3. Both of these features help to improve resolution and accuracy of the position measurements. The fine COSA sensor coil 25-1 is illustrated in plan view in FIG. 18a. As before, it comprises conductors arranged as largely radial spokes connected together using vias towards the inner and outer board radii. These spoke connecting conductors are largely implemented on layers 1 and 2 of the sensor PCB 1′, although there is also one trace per lobe implemented on layer 3 towards the outer radius of the design to help fit so many traces in a small space.

The fine SINA sensor coil 25-2 is shown in FIG. 18b and is almost exactly identical to the COSA coil 25-1 except rotated by 18°—relative to the fine COSA sensor coil 25-1 such that its inductive coupling is in spatial phase quadrature (90° electrically out of phase) with that of the fine COSA sensor coil 25-1.

Coarse COSB sensor coil 25-3 and coarse SINB sensor coil 25-4 are implemented largely adjacent the radial spokes of the fine sensor coils 25-1 and 25-2. The coarse COSB sensor coil 25-3 is largely implemented on layer 3 shown in FIG. 17c, and the coarse SINB sensor coil 25-4 is largely implemented on layer 4 shown in FIG. 17d. Note that with this design, neither of the coarse sensor coils 25-3 or 25-4 has loops implemented on layer 1 or 2 which carry the majority of the fine sensor coils 25-1 and 25-2. This is because space was available for several loops of each coarse coil on layers 3 and 4. This extra space is available because the inner and outer connecting vias are more spread out in the circumferential direction, allowing each to occupy a smaller radial extent.

The excitation coil 23 comprises 4 turns near the outer radius of the sensor board 1′, of which one is outside the outer connecting vias and 3 are inside. The excitation coil 23 has a further 4 turns wound in the opposite direction on layers 3 and 4. These additional 4 turns that are wound in opposite direction help to reduce magnetic emissions at the excitation frequency due to a reduction in effective loop area, while maintaining high coupling between the excitation coil 23 and the resonator coil 9. As shown in FIG. 18e, the sensor board 1′ vias towards the inner edge of the circuit board 1′ that are arranged in two rings and these 4 inner turns of the excitation coil 23 are wound between these two rings of vias. The radius of these 4 inner turns of the excitation coil 23 therefore matches the inner conductors that connect the radial spokes of the fine sensor coils. By minimising the diameter of the excitation coil's inner turns, its overall loop area is maximised, and hence coupling to the resonator coil, yielding maximum signal levels for best sensing resolution and accuracy.

The matching resonator PCB 6′ has 4 conductor layers that are illustrated in FIGS. 19a to 19d. The resonator coil's 9 path is traced in FIG. 20, which also shows (using the “+” and “−” signs) the magnetic field direction for each lobe.

Resonator PCB 6 layers 1 and 2 include 5 coil lobes circumferentially spaced to match the periodicity of the fine sensor coils 25-1 and 25-2 on the sensor PCB 1′ illustrated in FIG. 18. As before, an inward spiral coil on one of these layers is paired with an outward spiral coil on an adjacent layer to improve symmetry and therefore accuracy. These 5 coil lobes generate a largely sinusoidal variation in field around the rotation axis with 5 repeats per circle, and also have a DC, uniform component that enables the excitation to couple with the resonator coil 9 with roughly the same magnitude and the same direction irrespective of angle.

Resonator PCB layers 3 and 4 include 6 coil lobes, unlike the resonator coil design of FIG. 15 which only had 2 coil lobes on layers 3 and 4. The 3 coil lobes to the right generate positive magnetic field in response to a resonator current while those to the left generate a negative field for the same current direction. This means that these coil lobes have the same property described above, that the left hand coils are anti-symmetric versions of the right hand coils, with a very similar winding design but with current and hence field direction reversed. This works in the same way described above to improve immunity to misalignment in for position measurements taken by both coarse and fine sensor coils. The 3 coil lobes to the right are arranged to coincide with positive lobes of the fine COSA sensor coil 25-1 when both sensor and target are angled as drawn, while the left hand 3 lobes are arranged to coincide with negative lobes of the fine SINA sensor coil 25-2. This ensures maximum coupling between resonator coil lobes on layers 3 and 4 and the fine sensor coils 25-1 and 25-2. The angular extent of each of these 6 coils is adjusted during the design process to maximise coupling to the fine sensor coils 25-1 and 25-2, while also minimising unwanted spatial harmonics that otherwise cause errors. As before, having positive magnetic field generating lobes to the right and negative field generating lobes to the left means that the layer 3 and 4 resonator coil lobes also couple strongly with the coarse sensor coils 25-3 and 25-4.

This larger resonator PCB 6′ is only implemented on 4 layers instead of the 6 layers used for the smaller resonator PCB 6 described earlier. This is because the larger diameter circuit board helps achieve a higher Q-factor, and the additional layers are not required.

The coils of the resonator PCB 6 described above and shown in FIG. 15 couple with fine sensor coils having 3 repeats around the rotation axis, while the coils of the resonator PCB 6′ shown in FIG. 19 couple with fine sensor coils having 5 repeats around the rotation axis. The number of repeats can be modified, together with the number of fine periods of the matching sensor coils 25. This number of repeats must, however, be odd, so that the resonator PCB 6 includes a set of loops where the left and right hand portions have anti-symmetry. This is because fine sensor coils with odd periodicity have the same anti-symmetry, whereas fine sensor coils that repeat an even number of times about the rotation axis have left-right symmetry, not anti-symmetry.

In the descriptions of resonator coils 9 above, references to left and right refer to the resonator coil portions as drawn, and in each case there is also a large amount of top to bottom symmetry, with coil portions above a centre line drawn left to right are almost mirror images of those below. At least from the perspective of generating magnetic fields, where it makes little difference whether coils are wound clockwise or anticlockwise, and which layer they are implemented on. More generally, a resonator coil 9 could be rotated to any angle, so it is important to clarify what symmetries to expect irrespective of rotation angle. It should be possible to identify two groups of resonator coil windings inside the target, one primarily repeating around the rotation axis the same number of times that the fine sensor coils do, and another group that largely has mirror symmetry about a first line passing through the rotation axis and anti-symmetry about a second line perpendicular to the first.

### Alternatives

As those skilled in the art will appreciate, a number of modifications and alternatives can be made to the above embodiments whilst still benefiting from the inventions embodied therein. A few of these alternatives will now be described.

The embodiments described above used coarse sensor coils 25-3 and 25-4 that had one repeat per revolution of the target 3. In an alternative design, the coarse sensor coils 25-3 and 25-4 may have multiple repeats per revolution. Absolute position can then be determined by the spatial phase difference measured between the fine and coarse sensor coils.

In the resonator design shown in FIG. 15, the resonator coil 9 included a first portion having three sets of loops separated by approximately 120 degrees around the resonator PCB 6 (on layers 1, 2, 5 and 6) and a second portion having two sets of loops on opposite sides of the PCB 6 (on layers 3 and 4). In an alternative resonator coil design, the second portion (on layers 3 and 4) may be replaced with the four sets of loops shown in FIG. 21. The two sets of loops on the left hand side are wound in the same direction which is opposite to the winding direction of the two sets of loops on the right hand side, Therefore, these sets of loops have the same left-right anti-symmetry as before. The two left hand sets of loops are positioned to roughly coincide (overlap) with the two sets of loops on the left hand side of layers 1, 2, 5 and 6 and are wound in the same direction as those sets of loops. This arrangement will work substantially the same as the resonator coil illustrated in FIG. 15. However, with this design, the signals from the coarse sensor coils 25-3 and 25-4 must be reversed because the coarse component of the resonator magnetic field now has the opposite polarity to before (with a positive field on the left and a negative field on the right—c.f. FIG. 15a).

The embodiments described above used COS/SIN coil pairs: a 2-phase arrangement. It is equally applicable to use multi-phase coils, for example a 3-phase (a, b, c) arrangement illustrated in WO2008139216.

The sensor boards described in the above embodiments used sensor coils that span a full 360° of rotation. The coils may instead span a smaller angular range to provide an “arc” sensor.

The sensor systems described above used a resonant target powered from an excitation coil on the sensor PCB. The exact form of the excitation coil is not important, provided that it powers the resonator across the angular angles of interest. Alternatively, current may be directly driven into the target's windings by processing electronics, for example by wires or slip rings. Alternatively still, the target 3 may be self powered and may directly generate a target magnetic field.

In the embodiments described above, the resonator coil portions were connected in series with a capacitor to form the resonant circuit. Alternatively, the resonator coil portions may all be connected in parallel with the capacitor.

The embodiments described above used excitation coils 23 that generate largely uniform magnetic fields and the sensor coils 25 were patterned for a sinusoidal signal variation. As those skilled in the art will appreciate, the functions of the excitation coil and of the sensor coils may be reversed. In this case, two coils could be used to excite the target and one coil could be used to detect the signal back from the target in response to the two excitations. Alternatively, both excitation and sensor coils may be patterned with sinusoidally varying fields, each having a different periodicity. The reader is referred to WO98/58237 for details of how such reverse operation may be achieved.

In the embodiments described above, the sensor board 1 was fixed and the resonator board 6 moved relative to the sensor board. In alternative embodiments, the sensor board may move as well as the resonator board or the sensor board may move alone and the resonator board may be fixed.

In the above sensor designs, the excitation and sensor coils were formed as conductor tracks on a printed circuit board. As those skilled in the art will appreciate the excitation and sensor coils may be formed using any conductive material, such as conductive inks which can be printed on an appropriate substrate or conductive wire wound in the appropriate manner. Additionally, it is not essential for the, or each, excitation coil and the, or each, sensor coil to be mounted on the same member. For example, two separate printed circuit boards may be provided, one carrying the excitation coil(s) and the other carrying the, or each, sensor coil.

In the above embodiments, the target included a resonator that was energised by driving the, or each, excitation coil and a signal was generated in the, or each, sensor coil that varied with the position of the target relative to the sensor board. As those skilled in the art will appreciate, the use of such a resonator is not essential. Other electromagnetic devices may be used. For example, a short circuit coil, a metallic screen or a piece of ferrite may be used.

In the above embodiments, a resistor having a large impedance was switched into circuit to effectively decouple the capacitor C_SL from the excitation coil. In an alternative embodiment, instead of switching in a large resistor, an open circuit could be introduced in the place of resistor R_D.

In the above embodiments, reference was made to positive and negative magnetic fields produced by the different sets of loops of the resonator coil 9. Those skilled in the art will understand that this description is for ease of understanding the winding directions of the different sets of loops, as the polarity of the magnetic fields will be constantly reversing polarity due to the AC nature of the excitation current.

1. A transducer for an inductive position sensor comprising:
first and second members mounted for relative movement along a measurement path;
wherein the first member comprises:
at least one coarse sensor coil having sensor coil portions that are spatially arranged over a measurement path to provide coarse position sensing information; and
at least one fine sensor coil having sensor coil portions that are spatially arranged over the measurement path to provide fine position sensing information;
wherein the second member comprises a magnetic field generator having first and second magnetic field generating portions, wherein the first magnetic field generating portion comprises plural sets of coil loops that are spatially arranged over the measurement path to correspond to the sensor coil portions of the at least one fine sensor coil and wherein the second magnetic field generating portion comprises at least first and second sets of coil loops that are spatially arranged over the measurement path in an anti-symmetric manner;
wherein the first set of coil loops of the second magnetic field generating portion overlaps with a third set of coil loops which is one of said plural sets of coil loops of the first magnetic field generating portion;
wherein the sets of coil loops of the first and second magnetic field generating portions are connected together so that when a current is flowing in the sets of coil loops of the magnetic field generator: i) a current flow direction of the current in the first set of coil loops is opposite to a current flow direction of the current in the second set of coil loops; and ii) a current flow direction of the current in the third set of coil loops is the same as the current flow direction of the current in the first set of coil loops.

2. The transducer according to claim 1, wherein the at least one coarse sensor coil comprises first and second sets of coil loops spaced apart over the measurement path and connected in series so that an Electro Motive Force, (EMF), generated in the first set of coil loops by a common magnetic field opposes an EMF generated in the second set of coil loops by the common magnetic field.

3. (canceled)

4. The transducer according to claim 1, wherein the measurement path is circular and wherein the first and second sets of coil loops are arranged on either side of a diameter of the circular measurement path.

5. The transducer according to claim 1, wherein the at least one fine sensor coil has a repeating pattern of sensor coil portions arranged over the measurement path and wherein the plural sets of coil loops of the first magnetic field generating portion have a set of coil loops corresponding to each repetition of the repeating pattern of the sensor coil portions.

6. A transducer for an inductive position sensor comprising a printed circuit board carrying a plurality of sensor coils including first and second coarse sensor coils for providing coarse position information, first and second fine sensor coils for providing fine position information and an excitation coil for energising a target; wherein the plurality of sensor coils are formed by conductor tracks on different layers of the printed circuit board that are connected together to define the plurality of sensor coils at a plurality of vias that connect together conductors on the different layers of the printed circuit board;
wherein the printed circuit board comprises a through hole, a first plurality of vias arranged in first and second rings around the through hole and a second plurality of vias arranged in a third ring in proximity to an outer edge of the printed circuit board; wherein the fine sensor coils include radial conductor portions on a first layer of the printed circuit board that extend from vias in the first or second rings to vias in the third ring, wherein radial conductor portions of one of the fine sensor coils are connected to other radial conductor portions of the same one of the fine sensor coils on a second layer and wherein conductor coil portions of at least one coarse sensor coil or conductor coil portions of the excitation coil run in a space between the first and second rings of vias.

7. The transducer according to claim 6, wherein conductor coil portions of at least one coarse sensor coil run in a space between the first and second rings of vias.

8. The transducer according to claim 6, wherein conductor coil portions of the excitation coil run in a space between the first and second rings of vias.

9. A transducer for an inductive position sensor, the transducer comprising a multi-layer printed circuit board, each layer comprising conductor portions that connect together through the layers at a plurality of vias to define a plurality of coil loop portions;
wherein the printed circuit board includes a through hole and the plurality of coil loop portions include a first subset of coil loop portions, a second subset of coil loop portions and a third subset of coil loop portions;
wherein loops defined by the first subset of coil loop portions and the second subset of coil loop portions do not enclose the through hole and are arranged peripherally around the through hole;
wherein loops defined by the third subset of coil loop portions enclose the through hole;
wherein the plurality of coil loop portions are connected together so that a current flow direction in the first subset of coil loop portions is opposite to a current flow direction in the second subset of coil loop portions and is the same as a current flow direction in the third subset of coil loop portions, whereby when current flows through the first, second and third subsets of coil loop portions, magnetic fields generated by the plurality of coil loop portions combine to reduce a net magnetic flux through said through hole.

10. The transducer of claim 9, wherein the plurality of coil loop portions are arranged so that when current flows through the first, second and third subsets of coil loop portions, magnetic fields generated by the plurality of coil loop portions combine to minimise the net magnetic flux through said through hole.

11. The transducer of claim 9, wherein the plurality of coil loop portions are arranged so that when current flows through the first, second and third subsets of coil loop portions, magnetic fields generated by the plurality of coil loop portions combine so that there is no net magnetic flux through said through hole.

12. The transducer of claim 9, wherein the first subset of coil loop portions comprises more coil loop portions than the second subset of coil loop portions.

13. The transducer according to claim 9, wherein each coil loop portion defines a plurality of coil loops.

14. The transducer according to claim 9, wherein the plurality of coil loop portions are connected to one or more capacitors to form a resonant circuit.

15. The transducer according to claim 9, wherein, in the through hole, the magnetic fields generated by the second and third subsets of coil loop portions balance with the magnetic fields generated by the first subset of coil loop portions, thereby minimising magnetic coupling between any metal in the through hole and the plurality of coil loop portions.

16. Excitation circuitry for energising an excitation coil to excite a resonant target of an inductive position sensor, the excitation circuitry comprising:
an impedance network that is coupled, in use, to the excitation coil and having a first state that presents a first impedance that is primarily capacitive to the excitation coil and a second state that presents a second impedance to the excitation coil, wherein a magnitude of the second impedance is at least twice that of the first impedance when measured at the target's resonant frequency;
drive circuitry for driving the excitation coil via the impedance network with an excitation current to cause the excitation coil to generate an excitation magnetic field for energising the resonant target; and
a controller for controlling the drive circuitry and the impedance network so that in a first time period, the impedance network is configured in said first state and the drive circuitry is configured to drive the excitation coil with said excitation current and so that in a second time period, the impedance network is configured in said second state and the drive circuitry is configured not to drive the excitation coil with said excitation current.

17. The excitation circuitry according to claim 16, wherein the second impedance is primarily resistive, such that a resistive part of the second impedance is greater than a magnitude of a reactive part of the second impedance when measured at the target's resonant frequency.

18. The excitation circuitry according to claim 17, wherein the impedance network comprises at least one a capacitor that is coupled, in use, to the excitation coil and at least one resistive impedance that is couplable to and decouplable from the capacitor.

19. The excitation circuitry according to claim 18, wherein said control circuitry is arranged to decouple the at least one resistive impedance from the at least one capacitor during said first period and is configured to couple the at least one resistive impedance to the at least one capacitor during said second period.

20. The excitation circuitry according to claim 19, wherein the control circuitry is configured to couple the at least one resistive impedance in series with the at least one capacitor for reducing current flow in the excitation coil during the second period.

21. The excitation circuitry according to claim 16, wherein during the first time period, a resonant frequency of the excitation coil and the impedance network is between 1.5 and 6 times a resonant frequency of the resonant target.

22. The excitation circuitry according to claim 16, wherein the second impedance is an open circuit.

23-39. (canceled)
